(19) United States
(12) Patent Application Publication
(10) Pub. No.: US 2004/0107910 A1
(43) Pub. Date: Jun. 10, 2004

(54) Plasma processing apparatus and plasma processing method

(76) Inventors: Yukihiko Nakata, Yokohama-shi (JP); Kazufumi Azuma, Yokohama-shi (JP); Tetsuya Okamoto, Yokohama-shi (JP); Masashi Goto, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/727,250

(22) Filed: Dec. 4, 2003

(30) Foreign Application Priority Data
Dec. 5, 2002 (JP) 2002-353492
Dec. 18, 2002 (JP) 2002-366842

(51) Int. Cl. C23C 16/00

(52) U.S. Cl. 118/723 MW

(57) ABSTRACT

Disclosed is a plasma processing apparatus for performing a plasma processing, comprising an electromagnetic wave source for generating an electromagnetic wave, a rectangular waveguide, a plurality of slots formed in the rectangular waveguide and constituting a waveguide antenna, an electromagnetic wave radiation window consisting of a dielectric body, and a vacuum chamber, wherein a plasma is generated by an electromagnetic wave radiated from the slots into the vacuum chamber through the electromagnetic wave radiation window, the plasma processing apparatus being constructed to include an electromagnetic wave distributing waveguide portion for distributing the electromagnetic wave generated from the electromagnetic wave source into each of the waveguides, the plural waveguides being branched from the electric field plane or a plane perpendicular to the magnetic field plane of the electromagnetic wave distributing waveguide portion.

### CROSS-REFERENCE TO RELATED APPLICATIONS

This application is based upon and claims the benefit of priority from the prior Japanese Patent Applications No. 2002-353492, filed Dec. 5, 2002; and No. 2002-366842, filed Dec. 18, 2002, the entire contents of both of which are incorporated herein by reference.

### BACKGROUND OF THE INVENTION

1. Field of the Invention

The present invention relates to a plasma processing apparatus and plasma processing method, particularly, to a plasma processing apparatus and a plasma processing method for applying a plasma processing such as a film deposition, a surface modification or an etching to a large rectangular substrate. Also, the present invention can be suitably utilized for the manufacture of various displays such as a liquid crystal display, an EL, and a plasma display.

2. Description of the Related Art

In order to apply a plasma processing such as a film deposition, a surface modification, or an etching in the manufacturing process of, for example, semiconductor devices or liquid crystal displays, it was customary to use, for example, a parallel plate type high frequency plasma processing apparatus or an electron cyclone resonance (ECR) plasma processing apparatus.

However, in the parallel plate type plasma processing apparatus, the plasma density is low, and the electron temperature is high. Also, in the ECR plasma processing apparatus, a DC magnetic field is required for the plasma excitation, resulting in the problem that it is difficult to process a large area.

On the other hand, in recent years it is proposed a plasma processing apparatus which does not necessitate the magnetic field for the plasma generation and which is capable of forming a plasma with a high density and a low electron temperature.

The particular plasma processing apparatus will now be described.

(First Conventional Apparatus)

FIG. 24A is an upper view showing the construction of the first conventional plasma processing apparatus, and FIG. 24B is a cross sectional view showing the construction of the plasma processing apparatus shown in FIG. 24A. The plasma processing apparatus shown in these drawings is disclosed in Jpn. Pat. Appln. KOKAI Publication No. 9-63793.

A reference numeral 75 shown in the drawing denotes a vacuum chamber. An electromagnetic wave radiation window 74 consisting of a dielectric constitutes a part of the upper wall of the vacuum chamber 75. Each of a gas inlet 76 and a gas evacuation port 77 is formed in the vacuum chamber 75. A substrate support table 79 is arranged within the vacuum chamber 75, and a substrate 78 that is to be subjected to the plasma processing is set on the substrate support table 79. A circular micro wave radiation plate 73 is arranged on the electromagnetic wave radiation window 74. A plurality of slots 72 are concentrically arranged on the circular micro wave radiation plate 73, as shown in FIG. 24A. A coaxial transmission cable 71 is connected to the central portion of the circular micro wave radiation plate 73. A micro wave power is supplied from the coaxial transmission cable 71 to the circular micro wave radiation plate 73.

In the plasma processing apparatus shown in FIGS. 24A and 24B, the micro wave introduced from the coaxial transmission cable 71 toward the center of the circular micro wave radiation plate 73 is radiated from the slots 72 formed in the circular micro wave radiation plate 73 in order to form a uniform plasma within the vacuum chamber 75.

(Second Conventional Apparatus)

FIG. 25A is an upper view showing the construction of a second conventional plasma processing apparatus, and FIG. 25B is a cross sectional view showing the construction of the plasma processing apparatus shown in FIG. 25A. The plasma processing apparatus shown in these drawings is disclosed in Japanese Patent No. 2857090.

A reference numeral 85 shown in FIG. 25B denotes a vacuum chamber. An electromagnetic wave radiation window 84 consisting of a dielectric body constitutes a part of the upper wall of the vacuum chamber 84. Each of a gas inlet 86 and a gas evacuation port 87 is formed in the vacuum chamber 85. A substrate support table 89 is arranged within the vacuum chamber 85, and a substrate 88 that is to be subjected to the plasma processing is set on the substrate support table 89. A rectangular waveguide 81 is arranged in an upper portion of the vacuum chamber 85 with an electromagnetic wave radiation window 84 interposed therebetween. Also, two slots 82 constituting a waveguide antenna are formed in a lower portion of the rectangular waveguide 81. A micro wave source 83 is connected to the rectangular waveguide 81. Incidentally, a reference numeral 110 shown in FIG. 25B denotes a short circuit surface of the rectangular waveguide 81, and a reference numeral 111 shown in FIG. 25B denotes a magnetic field plane (H-plane) of the rectangular waveguide 81.

In the conventional plasma processing apparatus shown in FIGS. 25A and 25B, a micro wave power is supplied from the slots 82 arranged in a part of the H surface 111 of the rectangular waveguide 81 into the vacuum chamber 85 through the electromagnetic wave radiation window 84 so as to form a plasma within the vacuum chamber 85.

In the conventional plasma processing apparatus shown in FIGS. 25A and 25B, the width of each of the two slots 82 formed in the H surface 111 of the rectangular waveguide 81 is changed in order to make uniform the radiation power of the micro wave from the slots 82 from the view of the reflection of the micro wave at the reflecting surface of the rectangular waveguide 81. Incidentally, the change in the width of the slot 82 is not shown in FIG. 25A. However, as disclosed in the Japanese Patent quoted above, the slot 82 is shaped, for example, stepwise or tapered such that the slot 82 is rendered narrower toward the reflecting surface 110 of the rectangular waveguide 81.

The particular construction described above makes it possible to cause a relatively uniform plasma to be formed by the micro wave power radiated from the two slots 82, if the formed plasma is sufficiently diffused.

Incidentally, in the plasma processing apparatus used for manufacturing a semiconductor device or a liquid crystal display, the apparatus is rendered bulky in accordance with enlargement of the substrate size. Particularly, in the case of a liquid crystal display, a plasma processing apparatus is required for processing a substrate of about one meter square. The substrate of one meter square has an area about 10 times as large as the substrate of a 300 mm diameter, which is used for the manufacture of a semiconductor device.

Further, a reactive gas as such as a monosilane gas, an oxygen gas, a hydrogen gas, or a chlorine gas are utilized as the raw material gas in the plasma processing described above. A large amount of negative ions such as O⁻, H⁻, and Cl⁻ are present in the plasma using these reactive gases. Naturally, a manufacturing apparatus and a manufacturing method of a plasma, which are designed after consideration of the behaviors of these negative ions, are required.

(Third Conventional Apparatus)

FIG. 26A is a cross sectional view showing the construction of a third conventional plasma processing apparatus, and FIG. 26B is an upper view showing the construction of the conventional plasma processing apparatus shown in FIG. 26A. The conventional plasma processing apparatus shown in these drawings is disclosed in Japanese Patent Disclosure No. 2002-280196.

A reference numeral 105 shown in FIG. 26A denotes a vacuum chamber. An electromagnetic wave radiation window 104 consisting of a dielectric material constitutes a part of the upper wall of the vacuum chamber 105. Three columns of rectangular waveguides 101 are arranged in parallel on the vacuum chamber 105. Coupling holes 102 each constituting the waveguide antenna are formed in the bottom portion of the rectangular waveguide 101 in a manner to correspond to the electromagnetic wave radiation windows 104. As shown in FIG. 26B, each of the electromagnetic wave radiation windows 104 and the coupling holes 102 are formed to be successively enlarged toward the tip of the rectangular waveguide 101 (in the direction denoted by an arrow X). Incidentally, the substrate that is to be subjected to the plasma processing and the substrate support table, etc. are not shown in the drawings.

The apparatus shown in FIGS. 26A and 26B is a surface wave plasma processing apparatus in which three columns of the rectangular waveguides 101 are arranged in parallel. In this surface wave plasma processing apparatus, a plurality of rectangular waveguides 101 are arranged in parallel on the vacuum chamber 105. Also, the coupling holes 102 whose coupling coefficients are made successively larger toward the tip of the rectangular waveguide 101 are formed in each of the rectangular waveguides 101. Further, electromagnetic wave radiation windows 104 are formed keeping the vacuum between the electromagnetic wave radiation windows 104 and the rectangular waveguide 101 individually to correspond, respectively, to the coupling holes 102.

(Fourth Conventional Apparatus)

FIG. 27 is a cross sectional upper view showing the construction of a fourth conventional plasma processing apparatus. The conventional plasma processing apparatus is disclosed in Japanese Patent Disclosure No. 11-45799.

As shown in the drawing, a micro wave generated from a micro wave power source 1026 is transmitted through a waveguide 1023 so as to be introduced into a dielectric transmission path 1031 through an introducing portion 1311. The micro wave is transmitted through a matching section 1312 and, then, through a portion corresponding to a waveguide consisting of a partition plate 1314 and a rectangular portion 1313 so as to be introduced from a micro wave introducing port 1311 into a reaction chamber. Incidentally, a reference numeral 1003 denotes a micro wave radiation window.

(Fifth Conventional Apparatus)

FIG. 28 is a cross sectional upper view showing the construction of a fifth conventional plasma processing apparatus. The conventional plasma processing apparatus shown in FIG. 28 is disclosed in Japanese Patent Disclosure No. 11-111493.

In the plasma processing apparatus shown in the drawing, the micro wave supplied from a micro wave power source 1026 is transmitted through a micro wave distributor 1027 so as to be distributed to a waveguide 1028. Incidentally, a reference numeral 1002 shown in the drawing denotes a reaction chamber.

Also, the conventional plasma processing apparatus is also disclosed in, for example, “Proceeding of, 49^{th} Associated Meeting of Applied Physics Related Institutes, page 128, March, 2002” (non-patent literature 1), or “Proceeding of ESCAMPIG 16 & ICRP 5, page 321, Jul. 14-18, 2002” (non-patent literature 2).

However, each of the first to fifth conventional plasma processing apparatuses pointed out above gives rise to problems as pointed out below.

(Problems Inherent in First Conventional Plasma Processing Apparatus):

Where the micro wave is transmitted through a conductor such as the coaxial transmitting path 71 or a circular micro wave radiation plate 73 as in the first conventional plasma processing apparatus shown in FIGS. 24A and 24B, a transmission loss such as a copper loss is generated within the conductor. The transmission loss make a serious problem with increase in the frequency and with increase in the coaxial transmission distance or in the area of the emitting plate. Therefore, in a large apparatus conforming with a very large substrate for a liquid crystal display, the attenuation of the micro wave is large so as to make it difficult to achieve an efficient plasma formation.

Also, the plasma processing apparatus in which a micro wave is emitted from the circular micro wave radiation plate 73 is certainly adapted for the processing of a circular substrate such as a semiconductor device. However, when used for the processing of a rectangular substrate for a liquid crystal display, the particular plasma processing apparatus gives rise to the problem that the plasma is rendered nonuniform for the rectangular substrate.

It follows that the first conventional plasma processing apparatus gives rise to the problem that it is difficult to process a substrate having a large area, particularly, a rectangular substrate.

(Problems Inherent in Second Conventional Plasma Processing Apparatus):

It is possible to suppress the transmission loss to a low level in the case of the system in which the micro wave transmitted through the rectangular waveguide 81 is emitted from the two slots 82 as in the second conventional plasma processing apparatus shown in FIGS. 25A and 25B. However, in the case of a plasma in which a large amount of negative ions are present in the plasma, the ambipolar diffusion coefficient is diminished so as to give rise to the problem that the plasma is concentrated in the vicinity of the slots from which the micro wave is emitted. The problem is rendered more serious in the case where the plasma pressure is high. Therefore, it is difficult to apply a plasma processing to a large area in the case of using a gas containing, for example, oxygen, hydrogen and chlorine which easily generate minus ions. Particularly, the application of the plasma processing to a large area is rendered difficult in the case where the gas pressure is high. Further, since the distribution of the slots 82 constituting the waveguide antenna is localized and rendered nonuniform relative to processing surface of the substrate 88 to which the plasma processing is to be applied, the plasma density is rendered nonuniform.

(Problems Inherent in Third Conventional Plasma Processing Apparatus):

The third conventional plasma processing apparatus is capable of dealing with a substrate having an area larger than that of the substrate processed by the first conventional plasma processing apparatus. The micro wave is supplied from a single micro wave power source into a single rectangular waveguide in the third plasma processing apparatus as disclosed in non-patent literature 1 and non-patent literature 2 referred to previously, though the introducing method of the micro wave is not described in the Japanese Patent referred to previously. Therefore, a large number of micro wave power sources are required in the third conventional plasma processing apparatus. Particularly, where the plasma processing apparatus is rendered large in size, a serious problem is generated that a large number of micro wave power sources are required, and that the interference among these micro wave power sources must suppressed while operating these micro wave power sources simultaneously. What should also be noted is that, since the rectangular waveguides 101 are arranged apart from each other to obtain good uniformity considering the diffusion of the plasma, it is impossible to arrange the coupling holes 102 uniformly over the entire area that is to be subjected to the plasma processing so as to permit the plasma to be distributed uniformly.

In addition, since the electromagnetic wave radiation windows 104 are arranged to conform with the coupling holes 102, the number of points where the vacuum must be ensured is increased to conform with the number of coupling holes 102. It follows that the processing cost of the ceiling plate of the vacuum chamber 105 is increased so as to increase the apparatus price.

(Problems Inherent in Fourth Conventional Plasma Processing Apparatus):

As shown in FIGS. 26A and 26B, the fourth conventional plasma processing apparatus is constructed such that the micro wave is distributed in the matching section portion 1312 so as to be supplied into the waveguide (i.e., three waveguides partitioned by the partition plate 1314). In this apparatus, the introducing portion 1311, the matching section 1312 and the three waveguides are positioned on the same plane, it is certainly possible to decrease the height of the apparatus. However, since the transmission direction of the micro wave is equal to the direction of the three waveguides, it is difficult to distribute the micro wave uniformly into the three waveguides at the introducing portion 1311 and the matching section 1312. Also, it is difficult to supply uniformly the micro wave into a large number of waveguides. In addition, it is difficult for the fourth conventional plasma processing apparatus to make a large apparatus. Further, because of the presence of the introducing portion of the micro wave, the footprint of the apparatus is rendered large.

(Problems Inherent in Fifth Conventional Plasma Processing Apparatus):

In the fifth conventional plasma processing apparatus, the micro wave supplied from the micro wave power source 1026 is transmitted through the micro wave distributor 1027 so as to be distributed into the waveguide 1028. Although the micro wave distributor 1027 and the waveguide 1028 are positioned on the same plane, the micro wave distributor 1027 is large so as to increase the footprint of the plasma processing apparatus.

### BRIEF SUMMARY OF THE INVENTION

An object of the present invention is to provide a compact plasma processing apparatus capable of processing a substrate having a large area, having a small footprint, and low in height, and a plasma processing method using the particular plasma processing apparatus.

According to a first embodiment of the present invention, there is provided a plasma processing apparatus for performing a plasma processing, hereinafter referred to as a first plasma processing apparatus, comprising an electromagnetic wave source for generating an electromagnetic wave, a waveguide, a plurality of slots formed in the waveguide and constituting a waveguide antenna, an electromagnetic wave radiation window consisting of a dielectric, and a vacuum chamber, wherein a plasma is generated by an electromagnetic wave radiated from the slots into the vacuum chamber through the electromagnetic wave radiation window, the plasma processing apparatus includes a plurality of the waveguides, which are arranged in contact with each other, and an electromagnetic wave distributing waveguide portion for distributing the electromagnetic wave from the electromagnetic wave source into the plural waveguides, and that the electromagnetic wave radiation window constitutes a part of the wall of the vacuum chamber, and the vacuum condition is retained in the chamber between the electromagnetic wave radiation window and the other wall of the vacuum chamber.

According to a second embodiment of the present invention, there is provided a plasma processing apparatus for performing a plasma processing, hereinafter referred to as a second plasma processing apparatus, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of a dielectric and disposed to face the plural slots, and a vacuum chamber including the electromagnetic wave radiation window, wherein a plasma is generated by the electromagnetic wave radiated from the slots into the vacuum chamber through the electromagnetic wave radiation window, the plasma processing apparatus includes a plurality of the waveguides, that the electromagnetic wave distributing waveguide portion serves to distribute the electromagnetic wave from the electromagnetic wave source into each of the plural waveguides, and that each of the plural waveguides is branched from the electric field plane or a plane perpendicular to the magnetic field plane of the electromagnetic wave distributing waveguide portion.

According to a third embodiment of the present invention, there is provided a plasma processing apparatus for performing a plasma processing, hereinafter referred to as a third plasma processing apparatus, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of a dielectric and arranged to face the plural slots, and a vacuum chamber including the electromagnetic wave radiation window, wherein a plasma is generated by the electromagnetic wave radiated from the slots into the vacuum chamber through the electromagnetic wave radiation window, the third plasma processing apparatus includes a plurality of the waveguides, that the electromagnetic wave distributing waveguide portion serves to distribute the electromagnetic wave from the electromagnetic wave source into each of the plural waveguides, and that the transmission direction of the electromagnetic wave is bent at substantially right angles in the electromagnetic wave distributing waveguide portion so as to permit the electromagnetic wave to be distributed into the plural waveguides.

According to a fourth embodiment of the present invention, there is provided a plasma processing apparatus for performing a plasma processing, hereinafter referred to as a fourth plasma processing apparatus, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of an dielectric and arranged to face the plural slots, and a vacuum chamber arranged to include the electromagnetic wave radiation window, wherein the plasma processing apparatus is constructed such that a plasma is generated by the electromagnetic wave radiated from the slots into the vacuum chamber through the electromagnetic wave radiation window, that the plasma processing apparatus includes a plurality of the waveguides, that the electromagnetic wave distributing waveguide portion serves to distribute the electromagnetic wave generated from the electromagnetic wave source into each of the plural waveguides, that each of the plural waveguides is branched from the electric field plane of the electromagnetic wave distributing waveguide portion, and that the electromagnetic wave distributing waveguide portion and the plural waveguides are arranged on substantially the same plane.

According to a fifth embodiment of the present invention, there is provided a plasma processing apparatus for performing a plasma processing, hereinafter referred to as a fifth plasma processing apparatus, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of a dielectric and arranged to face the plural slots, and a vacuum chamber arranged to include the electromagnetic wave radiation window, wherein the plasma processing apparatus is constructed such that a plasma is generated by the electromagnetic wave radiated from the slots into the vacuum chamber through the electromagnetic wave radiation window so as to carry out the plasma processing, that the plasma processing apparatus includes a plurality of the waveguides, that the electromagnetic wave distributing waveguide portion serves to distribute the electromagnetic wave generated from the electromagnetic wave source into each of the waveguides, and that the shortest distance between the inner surfaces of the adjacent waveguides is not larger than the width between the inner surfaces of the waveguides.

According to a sixth embodiment of the present invention, there is provided a plasma processing apparatus for performing a plasma processing, hereinafter referred to as a sixth plasma processing apparatus, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of a dielectric and arranged to face the plural slots, and a vacuum chamber arranged to include the electromagnetic wave radiation window, wherein the sixth plasma processing apparatus is constructed such that a plasma is generated by the electromagnetic wave radiation from the slots into the vacuum chamber through the electromagnetic wave radiation window, that the plasma processing apparatus includes a plurality of the waveguides, that the electromagnetic wave distributing waveguide portion serves to distribute the electromagnetic wave generated from the electromagnetic wave source into each of the plural waveguides, and that the plural waveguides are branched from the electromagnetic wave distributing waveguide portion toward both side.

According to a seventh embodiment of the present invention, there is provided a plasma processing apparatus for performing a plasma processing, hereinafter referred to as a seventh plasma processing apparatus of the present invention, comprising an electromagnetic wave source for generating an electromagnetic wave, an electromagnetic wave distributing waveguide for distributing the electromagnetic wave generated from the electromagnetic wave source into a plural waveguides connected to the electromagnetic wave distributing waveguide, a plurality of slots formed in the waveguide and constituting a waveguide antenna, and a vacuum chamber maintaining a vacuum condition, wherein the seventh plasma processing apparatus is constructed such that an electromagnetic wave is emitted from the slots into the vacuum chamber so as to form a plasma, that at least the waveguide is arranged within the vacuum chamber, and that a dielectric constituting a part of the wall of the vacuum chamber is arranged in the waveguide or the electromagnetic wave distributing waveguide to keep a vacuum condition among a part of the wall of the waveguide, the dielectric and another part of the wall of the vacuum chamber and to permit the electromagnetic wave to be introduced into the vacuum chamber through the dielectric.

According to an eighth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein the slots are distributed substantially uniformly over the entire area that is to be subjected to the plasma processing.

According to a ninth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein a plurality of the electromagnetic wave radiation windows are hermetically arranged in a manner to correspond commonly to the plural slots, and the vacuum condition is maintained between the plural electromagnetic wave radiation windows and the vacuum chamber.

According to a tenth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

the electromagnetic wave radiation window substantially equal in width to the waveguide is arranged in a manner to correspond to each of the waveguides;

the major axis direction of the waveguide substantially coincides with that of the electromagnetic wave radiation window;

the length in the major axis direction of the waveguide substantially coincides with that of the electromagnetic wave radiation window; and

the period of the major axis of the waveguide substantially coincides with the that of the electromagnetic wave radiation window.

According to an eleventh embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein the dielectric body member commonly in contact with at least one electromagnetic wave radiation window is arranged within the vacuum chamber.

According to a twelfth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein the beam body supporting each of the electromagnetic wave radiation windows on the side of the vacuum chamber is covered with the dielectric body member at least.

According to a thirteenth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein a water cooling pipe for controlling the temperature is arranged within the beam body positioned between the adjacent electromagnetic wave radiation windows for supporting the electromagnetic wave radiation windows or in that portion of the beam body which is in contact with the waveguide.

According to a fourteenth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein a gas introducing pipe is formed within the vacuum chamber below the beam body positioned between the adjacent electromagnetic wave radiation windows for supporting the electromagnetic wave radiation windows or below that portion of the vacuum chamber which is in contact with the waveguide.

According to a fifteenth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein a gas introducing pipe is formed of a dielectric body within the vacuum chamber under the electromagnetic wave radiation windows or integrated the electromagnetic wave radiation windows.

### BRIEF DESCRIPTION OF THE SEVERAL VIEWS OF THE DRAWING

FIG. 1A is a cross sectional view showing the construction of a plasma processing apparatus according to embodiment 1 of the present invention, FIG. 1B shows in a magnified fashion of a portion 1B included in FIG. 1A, FIG. 1C is an upper view of the plasma processing apparatus shown in FIG. 1A, and FIG. 1D shows in a magnified figure of a portion of FIG. 1A;

FIG. 2 is a cross sectional view showing the other example of a rectangular waveguide in the plasma processing apparatus according to embodiment 1 of the present invention;

FIG. 3A is a cross sectional view showing the construction of a plasma processing apparatus according to embodiment 2 of the present invention, and FIG. 3B is an upper view of the plasma processing apparatus shown in FIG. 3A;

FIG. 4A is a cross sectional view showing the construction of a plasma processing apparatus according to embodiment 3 of the present invention, and FIG. 4B shows in a magnified figure of a portion 4B shown in FIG. 4A;

FIG. 5 is an upper view showing the arrangement of a water cooling pipe in the plasma processing apparatus according to the embodiment 3 of the present invention;

FIG. 6 is an upper view showing the arrangement of a gas inlet pipe provided with a plurality of gas inlets, the gas inlet pipe in the plasma processing apparatus according to embodiment 3 of the present invention;

FIG. 7A is a cross sectional view showing the construction of a plasma processing apparatus according to embodiment 4 of the present invention, and FIG. 7B is an upper view of the plasma processing apparatus shown in FIG. 7A;

FIG. 8 is an upper view showing the construction of a plasma processing apparatus according to embodiment 5 of the present invention;

FIG. 9A is a cross sectional view showing the construction of a plasma processing apparatus according to embodiment 6 of the present invention, and FIG. 9B is an upper view of the plasma processing apparatus shown in FIG. 9A;

FIG. 10 is an upper view showing the construction of a plasma processing apparatus according to embodiment 7 of the present invention;

FIG. 11A is a cross sectional view showing the construction of a plasma processing apparatus according to embodiment 8 of the present invention, and FIG. 11B is an upper view of the plasma processing apparatus shown in FIG. 11A;

FIG. 12 is an upper view showing the construction of a plasma processing apparatus according to embodiment 9 of the present invention;

FIG. 13A is a cross sectional view showing the construction of a plasma processing apparatus according to embodiment 10 of the present invention, and FIG. 13B is an upper view of the plasma processing apparatus shown in FIG. 13A;

FIG. 14 shows the construction of FIGS. 14A, 14B and 14C;

FIGS. 14A, 14B and 14C are process flow diagrams in the case of applying the present invention to an n-channel type and a p-channel type polycrystalline silicon thin film transistor;

FIGS. 15A to 15E are cross sectional views collectively showing the formation process of a polycrystalline silicon thin film transistors;

FIG. 16A is a cross sectional view showing the construction of a plasma processing apparatus according to embodiment 11 of the present invention, and FIG. 16B is an upper view of the plasma processing apparatus shown in FIG. 16A;

FIG. 17A is a cross sectional view showing the construction of a plasma processing apparatus according to embodiment 12 of the present invention, and FIG. 17B is an upper view of the plasma processing apparatus shown in FIG. 17A;

FIG. 18A is a cross sectional view showing the construction of a plasma processing apparatus according to embodiment 13 of the present invention, and FIG. 18B is an upper view of the plasma processing apparatus shown in FIG. 18A;

FIG. 19A is a cross sectional view showing the construction of a plasma processing apparatus according to embodiment 14 of the present invention, and FIG. 19B shows in a magnified figure of a portion 19B shown in FIG. 19A;

FIG. 20 is a cross sectional view showing the other example of a rectangular waveguide in the plasma processing apparatus according to embodiment 14 of the present invention;

FIG. 21 is an upper view schematically showing the arrangement of the water cooling pipe included in the plasma processing apparatus according to embodiment 14 of the present invention;

FIG. 22 is an upper view schematically showing the arrangement of a gas introducing pipe provided with a plurality of gas inlets, the gas introducing pipe being included in the plasma processing apparatus according to embodiment 14 of the present invention;

FIG. 23 is an upper view showing the construction of a plasma processing apparatus according to embodiment 15 of the present invention;

FIG. 24A is an upper view showing the construction of a first conventional plasma processing apparatus, and FIG. 24B is a cross sectional view showing the construction of the conventional plasma processing apparatus shown in FIG. 24A;

FIG. 25A is an upper view showing the construction of a second conventional plasma processing apparatus, and FIG. 25B is a cross sectional view showing the construction of the conventional plasma processing apparatus shown in FIG. 25A;

FIG. 26A is an upper view showing the construction of a third conventional plasma processing apparatus, and FIG. 26B is a cross sectional view showing the construction of the conventional plasma processing apparatus shown in FIG. 26A;

FIG. 27 is a cross sectional upper view showing the construction of a fourth conventional plasma processing apparatus; and

FIG. 28 is a cross sectional upper view showing the construction of a fifth conventional plasma processing apparatus.

### DETAILED DESCRIPTION OF THE INVENTION

Plasma processing apparatuses according to the first to seventh embodiments of the present invention will now be described.

1) According to a first embodiment of the present invention, there is provided a plasma processing apparatus for performing a plasma processing, comprising an electromagnetic wave source for generating an electromagnetic wave, a waveguide, a plurality of slots formed in the waveguide and constituting a waveguide antenna, an electromagnetic wave radiation window consisting of a dielectric, and a vacuum chamber, wherein a plasma is generated by an electromagnetic wave radiated from the slots into the vacuum chamber through the electromagnetic wave radiation window, the plasma processing apparatus includes a plurality of the waveguides, which are arranged in contact with each other, and an electromagnetic wave distributing waveguide portion for distributing the electromagnetic wave from the electromagnetic wave source into the plural waveguides, and that the electromagnetic wave radiation window constitutes a part of the wall of the vacuum chamber, and the vacuum condition is retained in the chamber defined between the electromagnetic wave radiation window and the other wall of the vacuum chamber.

In the first plasma processing apparatus of the present invention, the waveguides are arranged in contact with each other, with the result that it is possible to permit easily the slots to be distributed uniformly over the entire area to which the plasma processing is applied. Also, since the first plasma processing apparatus comprises a waveguide portion for distributing the electromagnetic wave from the electromagnetic wave power source into a plurality of waveguides, the structure for distributing the electromagnetic wave is rendered simple in construction and cheap. In addition, the volume of the mechanism for distributing the electromagnetic wave can be decreased. It follows that a substrate having a large area can be processed with a uniform plasma density.

It should also be noted that, in the first plasma processing apparatus of the present invention, an electromagnetic wave is supplied from a single electromagnetic wave source into a plurality of waveguides through the waveguide portion for distributing the electromagnetic wave. As a result, it is possible to use the equal frequencies in all the waveguides so as to facilitate the design of the antenna in a manner to radiate a uniform energy density. On the other hand, if the plural waveguides differ from each other in the frequency, it is necessary to design the antenna with the interference of the electromagnetic waves taken into account.

2) According to a second embodiment of the present invention, there is provided a plasma processing apparatus for performing a plasma processing, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of a dielectric and disposed to face the plural slots, and a vacuum chamber including the electromagnetic wave radiation window, wherein a plasma is generated by the electromagnetic wave radiated from the slots into the vacuum chamber through the electromagnetic wave radiation window, the plasma processing apparatus includes a plurality of the waveguides, that the electromagnetic wave distributing waveguide portion serves to distribute the electromagnetic wave from the electromagnetic wave source into each of the plural waveguides, and that each of the plural waveguides is branched from the electric field plane or a plane perpendicular to the magnetic field plane of the electromagnetic wave distributing waveguide portion.

According to the second plasma processing apparatus of the present invention, it is possible to process a substrate having a large area. Also, the footprint of the plasma processing apparatus can be diminished and the plasma density can be made uniform.

3) According to a third embodiment of the present invention, there is provided a plasma processing apparatus for performing a plasma processing, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of a dielectric and arranged to face the plural slots, and a vacuum chamber including the electromagnetic wave radiation window, wherein a plasma is generated by the electromagnetic wave radiated from the slots into the vacuum chamber through the electromagnetic wave radiation window, the third plasma processing apparatus includes a plurality of the waveguides, that the electromagnetic wave distributing waveguide portion serves to distribute the electromagnetic wave from the electromagnetic wave source into each of the plural waveguides, and that the transmission direction of the electromagnetic wave is bent at substantially right angles in the electromagnetic wave distributing waveguide portion so as to permit the electromagnetic wave to be distributed into the plural waveguides.

The third plasma processing apparatus of the present invention produces the effects similar to those produced by the second plasma processing apparatus of the present invention.

4) According to a fourth embodiment of the present invention, there is provided a plasma processing apparatus for performing a plasma processing, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of an dielectric and arranged to face the plural slots, and a vacuum chamber arranged to include the electromagnetic wave radiation window, wherein the plasma processing apparatus is constructed such that a plasma is generated by the electromagnetic wave radiated from the slots into the vacuum chamber through the electromagnetic wave radiation window, that the plasma processing apparatus includes a plurality of the waveguides, that the electromagnetic wave distributing waveguide portion serves to distribute the electromagnetic wave generated from the electromagnetic wave source into each of the plural waveguides, that each of the plural waveguides is branched from the electric field plane of the electromagnetic wave distributing waveguide portion, and that the electromagnetic wave distributing waveguide portion and the plural waveguides are arranged on substantially the same plane.

The fourth plasma processing apparatus of the present invention produces the effects similar to those produced by the second plasma processing apparatus of the present invention.

5) According to a fifth embodiment of the present invention, there is provided a plasma processing apparatus for performing a plasma processing, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of a dielectric and arranged to face the plural slots, and a vacuum chamber arranged to include the electromagnetic wave radiation window, wherein the plasma processing apparatus is constructed such that a plasma is generated by the electromagnetic wave radiated from the slots into the vacuum chamber through the electromagnetic wave radiation window so as to carry out the plasma processing, that the plasma processing apparatus includes a plurality of the waveguides, that the electromagnetic wave distributing waveguide portion serves to distribute the electromagnetic wave generated from the electromagnetic wave source into each of the waveguides, and that the shortest distance between the inner surfaces of the adjacent waveguides is not larger than the width between the inner surfaces of the waveguides.

The fifth plasma processing apparatus of the present invention produces the effects similar to those produced by the second plasma processing apparatus of the present invention.

6) According to a sixth embodiment of the present invention, there is provided a plasma processing apparatus for performing a plasma processing, comprising an electromagnetic wave source for generating an electromagnetic wave, an electromagnetic wave distributing waveguide portion for distributing the electromagnetic wave generated from the electromagnetic wave source into a plural waveguides connected to the electromagnetic wave distributing waveguide portion, a plurality of slots formed in the waveguide and constituting a waveguide antenna, an electromagnetic wave radiation window consisting of a dielectric and arranged to face the plural slots, and a vacuum chamber arranged to include the electromagnetic wave radiation window, wherein the sixth plasma processing apparatus is constructed such that a plasma is generated by the electromagnetic wave radiated from the slots into the vacuum chamber through the electromagnetic wave radiation window, that the plasma processing apparatus includes a plurality of the waveguides, that the electromagnetic wave distributing waveguide portion serves to distribute the electromagnetic wave generated from the electromagnetic wave source into each of the plural waveguides, and that the plural waveguides are branched from the electromagnetic wave distributing waveguide portion to the opposite direction.

The sixth plasma processing apparatus of the particular construction produces the effects similar to those produced by the second plasma processing apparatus of the present invention.

7) In the sixth plasma processing apparatus of the present invention, it is possible for the plural waveguides to be branched at substantially right angles from the electromagnetic wave distributing waveguide portion toward both sides. The particular construction permits the sixth plasma processing apparatus of the present invention to produce the effects similar to those produced by the second plasma processing apparatus of the present invention.

8) In the sixth plasma processing apparatus of the present invention, it is desirable for the electromagnetic wave distributing waveguide portion and the plural waveguides to be arranged on substantially the same plane. The particular construction permits the sixth plasma processing apparatus of the present invention to produce the effects similar to those produced by the second plasma processing apparatus of the present invention.

9) Further, it is desirable for the plasma processing apparatus defined in any of items 2) to 8) given above to be constructed to include a plurality of electromagnetic wave radiation windows such that a vacuum is maintained between the plural electromagnetic wave radiation windows and the vacuum chamber. Since a plurality electromagnetic wave radiation windows are formed, it is possible to decrease the thickness of the electromagnetic wave radiation window. It follows that it is possible to process a substrate having a large area with a uniform plasma density.

10) According to a seventh embodiment of the present invention, there is provided a plasma processing apparatus for performing a plasma processing, hereinafter referred to as a seventh plasma processing apparatus of the present invention, comprising an electromagnetic wave source for generating an electromagnetic wave, an electromagnetic wave distributing waveguide for transmitting the electromagnetic wave generated from the electromagnetic wave source, a waveguide connected to the electromagnetic wave distributing waveguide, a plurality of slots formed in the waveguide and constituting a waveguide antenna, and a vacuum chamber maintaining a vacuum condition, wherein the seventh plasma processing apparatus is constructed such that an electromagnetic wave is radiated from the slots into the vacuum chamber so as to form a plasma, that at least the waveguide is arranged within the vacuum chamber, and that a dielectric body member constituting a part of the wall of the vacuum chamber is arranged in the electromagnetic wave distributing waveguide or the waveguide so as to permit a vacuum condition to be maintained by a part of the wall of the waveguide, the dielectric body member and another part of the wall of the vacuum chamber and to permit the electromagnetic wave to be introduced into the vacuum chamber through the dielectric body member.

In the case where a waveguide is arranged within the vacuum chamber, the vacuum is maintained by the dielectric body member arranged within the waveguide, and the electromagnetic wave is introduced into the vacuum chamber through the dielectric body member. In this case, it is possible to diminish the dielectric body member and to decrease the thickness of the dielectric body member. It follows that a substrate having a large area can be processed with a uniform plasma density.

11) In the plasma processing apparatus defined in item 10) above, it is desirable for the dielectric body member to fill substantially the entire volume within the waveguide. In the case of employing the particular construction, it is possible to prevent a plasma from entering the waveguide arranged within the vacuum chamber. It follows that it is possible to prevent the waveguide from being damaged by the plasma.

12) It is possible for the plasma processing apparatus defined in item 10) or 11) given above to be constructed such that a water cooling pipe is arranged within the beam portion of the waveguide between adjacent slots of the plural slots.

Cooling is required because the beam portion of the waveguide is heated and deformed by the plasma. By arranging a water cooling pipe in the beam portion, it is possible to achieve the cooling efficiently without obstructing the plasma generation.

13) In the plasma processing apparatus defined in any of items 10) to 12) given above, it is possible for a gas inlet to be formed in the vacuum chamber below the beam body of the waveguide positioned between adjacent slots of the plural slots.

In the case of employing the particular construction, it is possible to supply a gas uniformly onto a large area, with the result that a plasma processing of a high uniformity can be carried out without obstructing the generation of the plasma.

14) It is possible for the plasma processing apparatus defined in any of items 10) to 13) given above to comprise a single electromagnetic wave source for supplying an electromagnetic wave into the waveguide.

15) It is possible for the plasma processing apparatus defined in any of items 10) to 13) given above to comprise a plurality of electromagnetic wave sources for supplying an electromagnetic wave into the waveguide.

Since the maximum output of the microwave source is limited, a large power can be handled by using a plurality of microwave sources.

16) In the plasma processing apparatus defined in item 34) given above, it is possible for the adjacent electromagnetic wave sources included in the plural electromagnetic wave sources to differ from each other in the frequency.

In the case of using a plurality of micro wave sources, an interference is brought about among the produced plasmas. However, the interference can be prevented by allowing the adjacent micro wave sources to differ from each other in the frequency.

17) In the plasma processing apparatus defined in any of items 10) to 16) given above, it is desirable for the electromagnetic wave source for supplying an electromagnetic wave to the waveguide to have a frequency of 2.45 GHz.

Presently, 2.45 GHz is used the standard frequency of the micro wave source and, thus, the micro wave source having a frequency of 2.45 GHz is cheap. In addition, there are various kinds of micro wave sources having a frequency of 2.45 GHz.

18) In the plasma processing apparatus defined in any of items 10) to 16) given above, it is possible for a slot to be formed in the electromagnetic wave distributing waveguide portion, too.

19) In the plasma processing apparatus defined in any of items 10) to 16) given above, it is possible for the plasma processing to be any of the plasma oxidation, the plasma film formation and the plasma etching.

Some embodiments of the present invention will now be described in detail with reference to the accompanying drawings. Throughout the drawings, the members of the apparatus performing the same functions are denoted by the same reference numerals so as to avoid the overlapping description.

20) According to an eighth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein the slots are distributed substantially uniformly over the entire area that is to be subjected to the plasma processing.

In this case, a substrate having a large area can be processed with a uniform plasma density.

21) According to a ninth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein a plurality of the electromagnetic wave radiation windows are hermetically arranged in a manner to correspond commonly to the plural slots, and the vacuum condition is maintained between the plural electromagnetic wave radiation windows and the vacuum chamber.

In the case, the electromagnetic wave radiation windows correspond to the plural slot and the electromagnetic wave radiation windows are plural. It is possible to lower the processing cost of the ceiling plate of the vacuum chamber so as to lower the cost of the apparatus. Also, since a plurality of electromagnetic wave radiation windows are formed, it is possible to decrease the thickness of the electromagnetic wave radiation window. It follows that a substrate having a large area can be processed with a uniform plasma density.

22) According to a tenth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

the electromagnetic wave radiation window substantially equal in width to the waveguide is arranged in a manner to correspond to each of the waveguides;

the major axis direction of the waveguide substantially coincides with that of the electromagnetic wave radiation window;

the length in the major axis direction of the waveguide substantially coincides with that of the electromagnetic wave radiation window; and

the period of the major axis of the waveguide substantially coincides with the that of the electromagnetic wave radiation window.

In the case of employing the particular construction described above, it is possible to introduce the electromagnetic wave effectively into the vacuum chamber without causing the electromagnetic wave to be intercepted by the beam body.

23) In the plasma processing apparatus defined in item 22) above, it is possible for the length in the major axis direction of the electromagnetic wave radiation window to be shorter than the length in the major axis direction of the waveguide. In the case of employing the particular construction, it is possible to further decrease the thickness of the electromagnetic wave radiation window.

24) According to an eleventh embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein the dielectric body member commonly in contact with at least one electromagnetic wave radiation window is arranged within the vacuum chamber.

In the case of employing the particular construction, the electromagnetic wave is expanded by the dielectric body member arranged in a lower portion of the waveguide antenna which contain the plural slots so as to make it possible to form a higher uniformity of the plasma than that in the case where the dielectric body member is not arranged.

25) According to a twelfth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein the beam body supporting each of the electromagnetic wave radiation windows on the side of the vacuum chamber is covered with the dielectric body member at least.

In the case of employing the particular construction, the electromagnetic wave is expanded by the dielectric body member covering vacuum chamber on the side of the vacuum chamber so as to make it possible to form a higher uniformity of the plasma than that in the case where the dielectric body member is not arranged.

26) According to a thirteenth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein a water cooling pipe for controlling the temperature is arranged within the beam body positioned between the adjacent electromagnetic wave radiation windows for supporting the electromagnetic wave radiation windows or in that portion of the beam body which is in contact with the waveguide.

Cooling is required because the beam body of the vacuum chamber and the sealing member of the electromagnetic wave radiation window are heated by the plasma so as to deform or to do damage to the beam body and the sealing member noted above. By arranging a water cooling pipe in the beam body, it is possible to achieve the cooling efficiently without obstructing the generation of the plasma.

27) According to a fourteenth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein a gas introducing pipe is formed within the vacuum chamber below the beam body positioned between the adjacent electromagnetic wave radiation windows for supporting the electromagnetic wave radiation windows or below that portion of the vacuum chamber which is in contact with the waveguide.

In the case of employing the particular construction, it is possible to supply a gas uniformly onto a large area, with the result that a plasma processing with a high uniformity can be carried out without obstructing the generation of the plasma.

28) According to a fifteenth embodiment of the present invention, there is provided a plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:

the plasma processing apparatus includes a plurality of the waveguides;

the electromagnetic wave distributing waveguide portion serves to distribute the electromagnetic wave generated from the electromagnetic wave source into each of the plural waveguides; and

wherein a gas introducing pipe is formed of a dielectric body within the vacuum chamber under the electromagnetic wave radiation windows or integrated the electromagnetic wave radiation windows.

29) It is possible for the plasma processing apparatus defined in any of items 1) to 28) given above to comprise a single electromagnetic wave source for supplying an electromagnetic wave into the plural waveguide.

30) It is possible for the plasma processing apparatus defined in any of items 1) to 28) given above to comprise a plurality of electromagnetic wave sources for supplying an electromagnetic wave into the plural waveguide.

Since the maximum output of the microwave source is limited, a large power can be supplied to the plasma processing apparatus by using a plurality of microwave sources.

31) In the plasma processing apparatus defined in item 30) given above, it is possible for the adjacent electromagnetic wave sources included in the plural electromagnetic wave sources to differ from each other in the frequency.

In the case of using a plurality of micro wave sources, an interference may occur among the produced plasmas. However, the interference can be prevented by allowing the adjacent micro wave sources to differ from each other in the frequency.

32) In the plasma processing apparatus defined in any of items 1) to 31) given above, it is desirable for the electromagnetic wave source to have a frequency of 2.45 GHz for supplying an electromagnetic wave to the waveguide.

Presently, 2.45 GHz is used the standard frequency of the micro wave source and, thus, the micro wave source having a frequency of 2.45 GHz has a low price. In addition, there are various kinds of micro wave sources having a frequency of 2.45 GHz.

33) In the plasma processing apparatus defined in any of items 1) to 32) given above, it is possible for a slot to be formed on the electromagnetic wave distributing waveguide portion, too.

34) In the plasma processing apparatus defined in any of items 1) to 33) given above, it is possible for the plasma processing to be one of the plasma oxidation, the plasma deposition and the plasma etching.

35) It is possible for the plasma processing apparatus defined in any of items 1) to 33) to be used for performing the plasma processing method in which the plasma oxidation and the plasma CVD method are carried out consecutively without breaking the vacuum.

It is also possible for the plasma processing apparatus defined in any of items 1) to 23) to be used for performing the plasma processing method in which either (i) film deposition by plasma oxidation or plasma CVD (ii) or plasma etching is performed. The film formation and the plasma etching may be combined flexibly.

In the case of employing the particular construction, it is possible to process a substrate having a large area. It is also possible carry out various plasma processing operations by using a plasma processing apparatus having a small footprint and a uniform plasma density.

36) In the plasma processing apparatus defined in any of items 10) to 18) given above, it is possible for the dielectric body member to fill substantially the entire volume within the waveguide. The particular construction makes it possible to prevent the plasma from entering the waveguide arranged within the vacuum chamber so as to prevent the damage done to, for example, the film formation by the plasma within the waveguide.

37) In the plasma processing apparatus defined in any of items 1) to 33) given above, it is desirable for a second dielectric body member covering the slot to be arranged within the vacuum chamber.

The particular construction makes it possible to prevent a plasma from entering the waveguide arranged within the vacuum chamber so as to prevent the damage done by the plasma within the waveguide. It should also be noted that the electromagnetic wave is expanded within the second dielectric body member arranged in a lower portion of the entire waveguide antenna formed of all of the plural slots, with the result that it is possible to form a plasma having a higher uniformity, compared with the case where the second dielectric body member is not arranged.

38) In the plasma processing apparatus defined in any of items 1) to 33) given above, it is possible to arrange a plurality of waveguides in contact with each other.

Where a plurality of waveguides are arranged in contact with each other, it is possible to permit easily the slots to be distributed uniformly over the entire area that is to be subjected to the plasma processing, with the result that a substrate having a large area can be processed with a uniform plasma density.

(Embodiment 1)

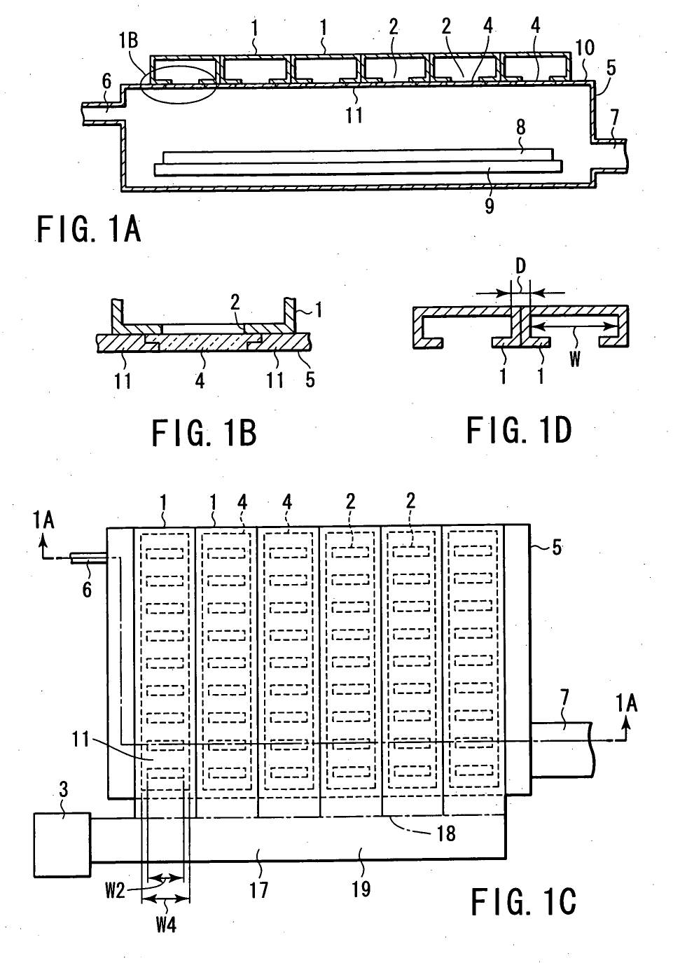

FIG. 1A is a cross sectional view showing the construction of a plasma processing apparatus according to embodiment 1 of the present invention, FIG. 1B shows in a magnified figure of a portion 1B shown in FIG. 1A, and FIG. 1C is an upper view of the plasma processing apparatus shown in FIG. 1A. It should be noted that FIG. 1A is a cross sectional view along the line 1A-1A shown in FIG. 1C.

A reference numeral 5 shown in the drawing denotes a vacuum chamber (plasma generating chamber) in which a plasma is generated. A substrate support table (stage) 9 is arranged within the vacuum chamber 5, and a target substrate 8 that is to be subjected to the plasma processing is set on the substrate support table 9. A gas inlet 6 for introducing a processing gas for carrying out the plasma processing into the vacuum chamber 5 is connected to an upper portion of the side wall of the vacuum chamber 5. On the other hand, a gas evacuation port 7 for evacuating the gas in the vacuum chamber 5 is connected to a lower portion of the side wall of the vacuum chamber 5.

A reference numeral 3 shown in the drawing denotes an electromagnetic wave source for generating a plasma, e.g., a micro wave source (electromagnetic wave source) for generating a micro wave having a frequency of, for example, 2.45 GHz. An electromagnetic wave distributing waveguide portion 17 is connected to the micro wave source 3 for transmitting the micro wave generated from the micro wave source. A plurality of rectangular waveguide 1, for example, a rectangular cross sectional shape, are connected to the electromagnetic wave distributing waveguide portion 17. As shown in the drawing, the plural rectangular waveguides 1 are branched from the electromagnetic wave distributing waveguide portion 17 at substantially right angles. Also, the plural rectangular waveguides 1 and the electromagnetic wave distributing waveguide portion 17 are arranged on substantially the same plane. The micro wave generated from the micro wave source 3 is distributed by the electromagnetic wave distributing waveguide portion 17 into the plural rectangular waveguides 1.

The construction that the plural waveguides 1 and the electromagnetic wave distributing waveguide portion 17 are arranged on the same plane makes it possible to achieve a compact construction having a small footprint. A plurality of slots 2 collectively constituting a waveguide antenna are formed on that surface of the rectangular waveguide 1 which faces the upper wall surface of the vacuum chamber 5. It should be noted that the slot 2 is shaped, for example, oblong. Also, the rectangular waveguides 1 are arranged such that the adjacent rectangular waveguide 1 are in contact with each other.

A reference numeral 10 shown in the drawing denotes the ceiling plate of the vacuum chamber 5. An oblong electromagnetic wave radiation window (electromagnetic wave introducing window) 4 made of a material that transmits the electromagnetic wave. It constitutes a part of the wall of the vacuum chamber 5, i.e., a part of the upper wall of the vacuum chamber 5, and the vacuum condition is maintained between the electromagnetic wave radiation window 4 and the beam body 11 constituting a part of the ceiling plate 10 by using an O-ring which made of rubber (not shown). In other words, the vacuum chamber 5 is caused to constitute a hermetic vessel by the electromagnetic wave radiation window 4 acting as the upper wall surface of the vacuum chamber 5. The materials which permit transmitting an electromagnetic wave include, for example, dielectric bodies such as quartz, glass and a ceramic materials. It is optimum to use quartz for forming the electromagnetic wave radiation window 4 in view of the resistance to heat caused by the plasma generation.

The electromagnetic wave radiation window (electromagnetic wave introducing window) 4 is divided into a plurality of sections for making the electromagnetic wave radiation window 4 relatively thin so as to allow the electromagnetic wave radiation window 4 to exhibit a pressure resistance. The pressure resistance noted above denotes the pressure resistance of the vacuum chamber 5. In embodiment 1, each of the electromagnetic wave radiation windows 4 is shaped oblong so as to face a plurality of slots 2. Also, a plurality of electromagnetic wave radiation windows 4, the beam body 11, etc. collectively constitute the ceiling plate 10 of the vacuum chamber 5.

A beam body 11 is arranged for hermetically supporting each of the oblong electromagnetic wave radiation windows 4. The beam body 11 is formed of a metal, e.g., aluminum, in order to prevent the beam body 11 from being deformed by the atmospheric pressure, the deformation causing deterioration in the hermetic properties of the vacuum chamber 5. To prevent the beam body 11 from being deformed by the plasma reaction heat, it is desirable for a cooling mechanism, e.g., a fluid passageway of a coolant, to be arranged within the beam body 11. It is desirable to use a flowing water as a coolant. It is possible to control the beam body 11 under a desired temperature by forming a water passageway within the beam body 11. A plurality of slots 2 constituting a waveguide antenna are formed in the rectangular waveguide 1. It is possible for the slot 2 to be formed of a hole made in the rectangular waveguide 1. Alternatively, it is possible to form the rectangular waveguide 1 by combining a plate having a hole formed in a separate member and another member.

The plural slots 2 are distributed substantially uniformly over the entire area that is to be subjected to the plasma processing. The distance between the two adjacent slots is determined to permit a uniform plasma to be generated within the vacuum chamber 5 or to permit an electromagnetic wave to be radiated uniformly within the vacuum chamber 5.

Where the shortest distance between the inner surfaces of the mutually facing pipe walls of the adjacent waveguides 1 is represented by D and the width between the facing inner surfaces of a single waveguide 1 is represented by W as shown in FIG. 1D, it is desirable for the distance D to be not larger than the width W. The reason for the particular relationship in size is to radiate the electromagnetic wave uniformly within the vacuum chamber 5. If the electromagnetic wave is radiated uniformly to the vacuum chamber 5, the plasma density within the vacuum chamber 5 is rendered uniform. It should be noted that the direction of the major axis of each of the waveguide 1 substantially coincides with the direction of the major axis of the electromagnetic wave radiation window 4. Also, the waveguide 1 coincides with the electromagnetic wave radiation window 4 in each of the length in the major axis direction and the period of the major axis. Further, the length in the major axis direction of the electromagnetic wave radiation window 4 is smaller than the length in the major axis direction of the waveguide 1.

The micro wave generated in the micro wave source 3 is transmitted from the linear electromagnetic wave distributing waveguide portion 17 and distributed into a plurality of waveguides 1. Then, the micro wave radiated from the slots 2 into the vacuum chamber 5 through the electromagnetic wave radiation window 4. The plane on which the plural waveguides 1 are branched from the electromagnetic wave distributing waveguide portion 17 is the electric field plane (E plane) 18, i.e., the plane perpendicular to the magnetic field plane (H plane) 19. Alternatively, where the electromagnetic wave distributing waveguide portion 17 is a rectangular waveguide as in embodiment 1 of the present invention, the plane noted above is said to be a waveguide plane having a shorter width. It follows that the transmitting direction of the electromagnetic wave can be bent at substantially the right angles in the portion of the electromagnetic wave distributing waveguide portion 17. As a result, the electromagnetic wave can be branched into a plurality of waveguides 1 easily, compared with the fourth conventional plasma processing apparatus and the fifth conventional plasma processing apparatus in which it is substantially impossible to bend the transmitting direction of the electromagnetic wave in the right angles. Such being the situation, the plasma processing apparatus according to embodiment 1 of the present invention is capable of dealing easily with a substrate having a large area and is featured in that the footprint of the branched portion is small.

As described above, the electromagnetic wave distributing waveguide portion 17 and the plural waveguides 1 are positioned substantially on the same plane. This system called a single layer type in contrast to a multi-layer type in which the electromagnetic wave distributing waveguide portion 17 and the plural waveguides 1 arranged in a multi-layer. The single layer type permits decreasing the height of the apparatus, compared with the multi-layer type, so as to make it possible to render compact the apparatus. Also, as described herein later, the single layer type can be manufactured with a low cost because the electromagnetic wave distributing waveguide portion 17 and the plural waveguides 1 can be prepared by grinding a single metal block, for example.

For example, as shown in FIG. 1C, the width W₄ of the electromagnetic wave radiation window 4 is set at 10 cm, and the width W₂ of the slot 2 is set shorter than the width W₄ of the electromagnetic wave radiation window 4 by several millimeters. If a plurality of electromagnetic wave radiation windows 4 are arranged so as to decrease the width W₄, an advantage can be obtained as follows. Specifically, it is possible to decease the thickness of the electromagnetic wave radiation window 4 so as to decrease the loss of the electromagnetic wave caused by the absorption in the electromagnetic wave radiation window 4. In addition, it is possible to provide a large plasma processing apparatus corresponding to a large substrate.

If the pressure within the vacuum chamber 5 is reduced, a difference in the gas pressure between atmospheric pressure and pressure substantially close to vacuum, i.e., about 9.80665×10⁴ Pa (1 kg/cm²), is applied to the electromagnetic wave radiation window 4. It follows that it is necessary to allow the electromagnetic wave radiation window 4 to have a thickness large enough to withstand the pressure difference noted above.

If the electromagnetic wave radiation window 4 is formed of, for example, a circular synthetic quartz plate having a diameter of 300 nm or a rectangular synthetic quartz plate sized at 250 mm×250 mm, it is necessary for the electromagnetic wave radiation window 4 to have a thickness of about 30 mm, as shown in Table 1 given below. If the thickness of the electromagnetic wave radiation window 4 is increased, the absorption loss of the electromagnetic wave is increased. When it comes to a plasma processing apparatus corresponding to a large substrate sized at about 1 m square, the thickness of the electromagnetic wave radiation window 4 is rendered excessively large so as to make it impossible to make the large plasma processing apparatus. Such being the situation, six electromagnetic wave radiation windows 4 each sized at 8 cm×55 cm are arranged in embodiment 1 of the present invention, and vacuum is maintained by the O-ring seal between these six electromagnetic wave radiation windows 4 and the vacuum chamber 5. As a result, it is possible to set the thickness of the electromagnetic wave radiation window 4 at 30 mm.

TABLE 1
Window Size and Required Thickness of Synthetic
Quarts Plate

| | diameter of | diameter | 250 mm | 300 mm |
|---|---|---|---|---|
| Window size | 6 inches | of 300 mm | square | square |
| Thickness of | 14.3 mm | 30 mm | 30.6 mm | 36.8 mm |
| synthetic | | | | |
| quarts plate | | | | |

The plasma processing apparatus according to embodiment 1 of the present invention comprises a micro wave source 3, a rectangular waveguide 1, a plurality of slots 2 formed in the rectangular waveguide 1 and constituting a waveguide antenna, an electromagnetic wave radiation window 4 made of a dielectric body, and a vacuum chamber 5. In the plasma processing apparatus of this embodiment, a plasma is generated by the electromagnetic wave (micro wave) radiated from the slots 2 into the vacuum chamber 5 through the electromagnetic wave radiation window 4 so as to perform the plasma processing. It should be noted that a plurality of waveguides 1 are used in this embodiment (six rectangular waveguides 1 being shown in the drawings). Also, the distance D between the inner surfaces of the mutually facing walls of the adjacent waveguides 1 is not larger than the width W between the mutually facing inner surfaces of the waveguide 1. Also, in embodiment 1 of the present invention, the plural rectangular waveguides 1 are arranged in contact with each other, and the plasma processing apparatus includes a waveguide portion, i.e., the electromagnetic wave distributing waveguide portion 17, for distributing the electromagnetic wave generated from the micro wave source 3 into the six rectangular waveguides 1. Further, a vacuum condition is maintained between the plural electromagnetic wave radiation windows 4 and the vacuum chamber 5. In addition, the plural slots 2 are distributed substantially uniformly over the entire area of the substrate 8 that is to be subjected to the plasma processing. What should also be noted is that arranged are a plurality of electromagnetic wave radiation windows 4 (6 electromagnetic wave radiation windows 4 in this case) commonly corresponding to a plurality of slots 2 (9 slots being shown in the drawings).

Embodiment 1 of the present invention produces prominent effects as pointed out below:

1) Arranged are a plurality of electromagnetic wave radiation windows 4 corresponding to a plurality of slots 2 formed in the rectangular waveguide 1. It follows that, since it suffices for mainly the electromagnetic wave radiation window 4 having a width of W₄ to withstand the difference in pressure between the atmospheric pressure and the pressure inside the vacuum chamber, it is possible to decrease the thickness of the electromagnetic wave radiation window 4. Such being the situation, it is possible to realize a large plasma processing apparatus so as to make it possible to process a substrate having a large area with a uniform plasma density.

2) Since a plurality of the rectangular waveguides are arranged in contact with each other, it is possible to distribute easily the slots uniformly over the entire area that is to be subjected to the plasma processing. It follows that a substrate having a large area can be processed with a uniform plasma density.

3) Further, an electromagnetic wave is supplied from a single electromagnetic wave source, i.e., the micro wave source 3 in this case, into a plurality of rectangular waveguides 1 through the electromagnetic wave distributing waveguide portion 17. It follows that it is possible to permit the frequencies of the electromagnetic waves within all the rectangular waveguides 1 to be equal to each other, with the result that an antenna that emits a uniform energy density can be designed easily. By contraries, if the frequencies noted above differ from each other, it is necessary to design the antenna with the interference of the electromagnetic waves taken into account.

4) Still further, since arranged are a plurality of electromagnetic wave radiation windows 4 commonly corresponding to a plurality of slots 2, it is possible to decrease the processing cost of the ceiling plate of the vacuum chamber 5 so as to decrease the manufacturing cost of the plasma processing apparatus, compared with the method of maintaining the vacuum condition for each slot 2.

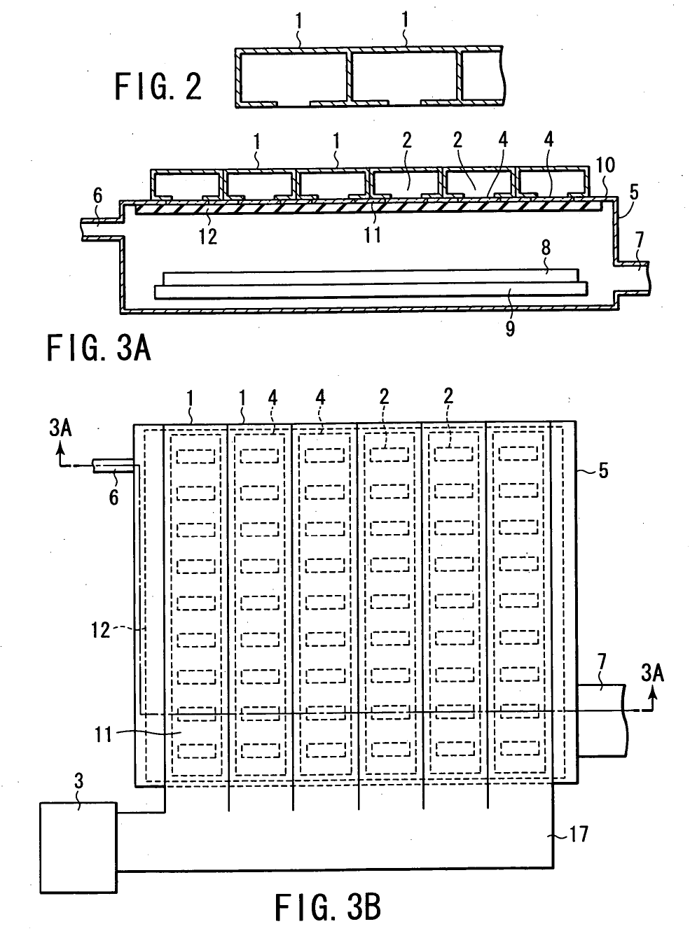

Incidentally, embodiment 1 covers the case where a plurality of rectangular waveguides 1 formed of different members are arranged in contact with each other as shown in FIG. 1A. However, it is also possible to arrange a rectangular waveguide 1 formed of a single member as shown in FIG. 2 in place of the plural rectangular waveguides 1 formed of different members.

Also, in the present invention, the technical idea of arranging a plurality of rectangular waveguides 1 in contact with each other naturally includes the idea that the distance D between inner surfaces of adjacent rectangular waveguides 1 is not larger than the width W between the inner surfaces of the waveguide 1. Further, it is possible to form the waveguide 1 and the electromagnetic wave distributing waveguide portion 17 by using a single member.

The basic idea of embodiment 1 is that a micro wave is distributed in a region of a large and square area by using the electromagnetic wave distributing waveguide portion 17 and a plurality of waveguides 1 branched at substantially right angles from the electromagnetic wave distributing waveguide portion 17 so as to permit the micro wave to be emitted from the slots 2 onto a large and square area through the electromagnetic wave radiation window 4 with a uniform energy density, thereby generating a plasma of a uniform plasma density.

In the third conventional plasma processing apparatus, a micro wave power is emitted from a coupling hole so as to form a plasma, as described in the paragraph (0028) of Japanese Patent Disclosure No. 2002-280196 referred to previously. However, since the waveguides are arranged a prescribed distance apart from each other, the generated plasma is expanded by the diffusion, with the result that the plasma density has a Gauss distribution. The Gauss distributions are superposed one upon the other in an attempt to make uniform the plasma density.

To be more specific, in embodiment 1 of the present invention, a plasma having a uniform plasma density is generated in a region of a large angular area by the plural rectangular waveguides 1 arranged in contact with each other. On the other hand, in the third conventional plasma processing apparatus, a plurality of waveguides are arranged a certain distance apart from each other, and the plasma densities each having a Gauss distribution are superposed one upon the other in an attempt to make uniform the plasma density.

The difference pointed out above between the plasma processing apparatus according to embodiment 1 of the present invention and the third conventional plasma processing apparatus will now be described with reference to the difference between the two in the manufacturing method of the waveguide.

Specifically, embodiment 1 of the present invention will now be described, covering the case where, for example, the effective processing area is 70 cm×60 cm. To be more specific, concerning an example of the specific manufacturing method of the rectangular waveguide 1, six rectangular waveguides 1 each having a width within the rectangular waveguide 1 of 9 cm and a height of 3 cm were prepared by grinding an aluminum block sized at 70 cm×60 cm×4 cm. In this case, the wall of the adjacent rectangular waveguides 1 was formed integral, as shown in FIG. 2.

It is possible to manufacture a waveguide planar antenna according to embodiment 1 of the present invention in also the method of preparing a plurality of rectangular waveguides 1 and assembling these plural rectangular waveguides 1 in contact with each other.

Further, it is possible to obtain the effect produced by embodiment 1 of the present invention even if these rectangular waveguides are formed slightly apart from each other as described previously.

Also, the relationship between a plurality of rectangular waveguides 1 and the electromagnetic wave radiation window 4 corresponds to each rectangular waveguide 1, and an electromagnetic wave radiation window 4 having a width slightly smaller than the width of the rectangular waveguide 1 is arranged as shown in FIG. 1C. The major axis direction of the rectangular waveguide 1 substantially coincides with that of the electromagnetic wave radiation window 4. The length in the major axis direction of the rectangular waveguide 1 substantially coincides with that of the electromagnetic wave radiation window 4. Further, the period of the major axis of the rectangular waveguide 1 substantially coincides with the period of the major axis of the electromagnetic wave radiation window 4. In this fashion, the electromagnetic wave radiation window 4 is formed in every rectangular waveguide 1, and the major axis direction, the length in the major axis direction and the period of the major axis of the electromagnetic wave radiation window 4 correspond to those of the rectangular waveguide 1 in embodiment 1 of the present invention. It follows that the electromagnetic wave can be effectively introduced uniformly into the vacuum chamber 5 without causing the electromagnetic wave to be intercepted by the beam body 11 even if the electromagnetic wave radiation window 4 is divided into a plurality of sections.

It is also possible to make the length in the major axis direction of the electromagnetic wave radiation window 4 shorter than the length in the major axis direction of the rectangular waveguide 1. In this case, the beam bodies 11 of the ceiling plate 10 of the vacuum chamber 5 supporting the electromagnetic wave radiation window 4 are formed to cross each other in the shape of a lattice. It follows that it is possible to form a small electromagnetic wave radiation window 4 shorter than the rectangular waveguide 1 and, thus, it is possible to further decrease the thickness of the electromagnetic wave radiation window 4.

Also, in embodiment 1 of the present invention, used is a single micro wave source 3 for supplying an electromagnetic wave into the rectangular waveguide 1, and the frequency of the micro wave source 3 is set at 2.45 GHz. Presently, 2.45 GHz is used the standard frequency of the micro wave source 3 and, thus, the micro wave source having a frequency of 2.45 GHz is manufactured on the mass production basis and has a low price. In addition, there are various kinds of micro wave sources having a frequency of 2.45 GHz.

Incidentally, the plasma processing carried out by the plasma processing apparatus according to embodiment 1 of the present invention includes a plasma oxidation, a plasma deposition, a plasma etching and a plasma ashing.

Also, a plasma processing can be applied to a substrate having a large and square area by using the plasma processing apparatus according to embodiment 1 of the present invention. Further, an electromagnetic wave such as a micro wave having a frequency higher than 13.56 MHz, which is generally used, is employed in the plasma processing apparatus according to embodiment 1 of the present invention. It follows that the plasma generated by the plasma processing apparatus of the present invention has a high electron density, a low electron temperature and is uniform so as to provide an excellent plasma processing method relating to the plasma oxidation, a plasma etching and a plasma film formation.

(Embodiment 2)

FIG. 3A is a cross sectional view showing the construction of a plasma processing apparatus according to embodiment 2 of the present invention, and FIG. 3B is an upper view of the plasma processing apparatus shown in FIG. 3A. Incidentally, FIG. 3A is a cross sectional view along the line 3A-3A shown in FIG. 3B. Embodiment 2 is directed to an example in which the nonuniformity of the plasma caused by the beam body 11 is suppressed so as to make the plasma uniform.

In embodiment 2 of the present invention, the beam body 11 is covered with a dielectric body at least, e.g., a dielectric body member 12, so as to facilitate the expansion of the plasma into the portion of the beam body 11, too. As described previously, the beam body 11, which serves to support a plurality of electromagnetic wave radiation windows 4, is formed of a metal in general. It is possible for the beam body 11 made of a metal to obstruct the uniform generation of the micro wave. In order to facilitate the expansion of the plasma into the portion of the beam body 11, at least the beam body 11 on the side of the inner surface of the vacuum chamber 5 (inner wall surface) is covered with the dielectric body member 12 so as to prevent, for example, the electrons contained in the plasma from disappearing in the beam body 11 formed of a metal. It is possible for the dielectric body member 12 to cover the beam body 11 alone within the vacuum chamber 5 at least.

In embodiment 2 of the present invention, at least one electromagnetic wave radiation window 4 is formed. In this case, the electromagnetic wave radiation windows are arranged to form 6 columns each having 9 electromagnetic wave radiation windows 4 included therein. In other words, 54 slots, i.e., 9×6 electromagnetic wave radiation windows, are covered by a single rectangular dielectric body member 12 which is located in an upper portion within the vacuum chamber 5.

In embodiment 2 of the present invention, an electromagnetic wave is easily expanded within the dielectric body member 12 formed in a lower portion of the entire waveguide antenna located of all the plural slots 2 in spite of the presence of the beam body 11 made of a metal to support a plurality of the electromagnetic wave radiation windows 4. Therefore, the beam body 11 is not exposed to the plasma. It follows that, in the case of arranging the dielectric body member 12, it is possible to form a plasma having a high uniformity, compared with the case where the dielectric body member 12 is not arranged.

Also, embodiment 2 described above covers the case where used is a single dielectric body member 12. However, it is possible to divide the dielectric body member 12 into a plurality of sections. Also, as described previously, the electrons, etc. are not caused to disappear by the beam body 11 so as to facilitate the expansion of the plasma, if at least the beam body 11 on the side of the inner surface of the vacuum chamber 5 is covered with a dielectric body member. Also, it is possible to form integrally the dielectric body member constituting the electromagnetic wave radiation window 4 and the dielectric body member covering the inner surface of the beam body 11.

(Embodiment 3)

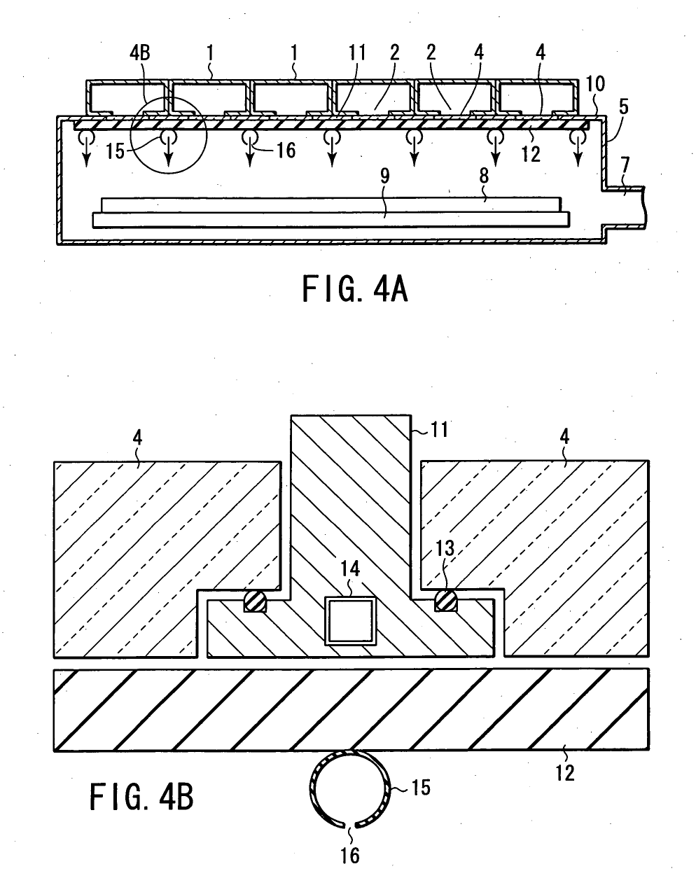

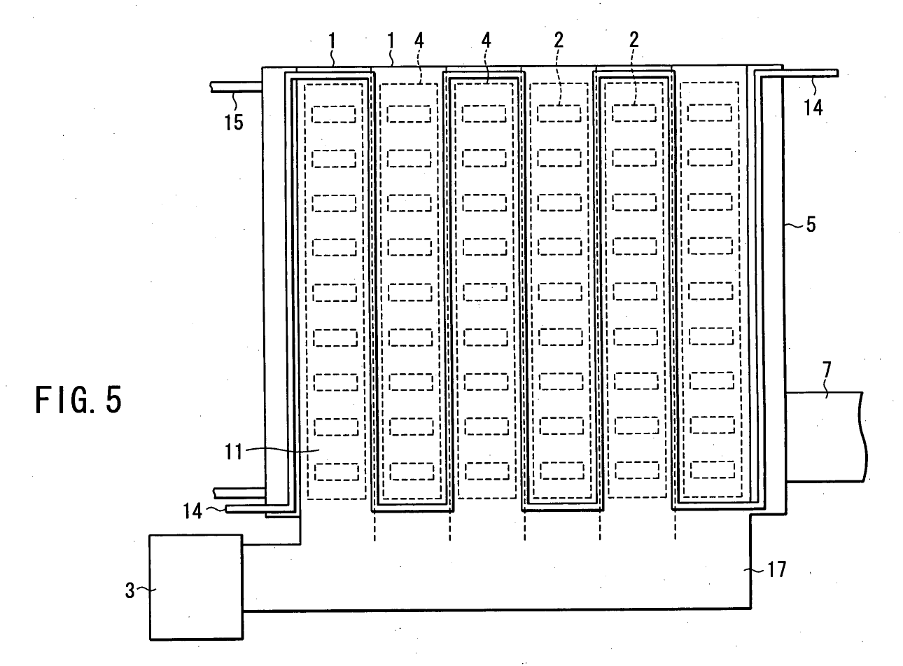

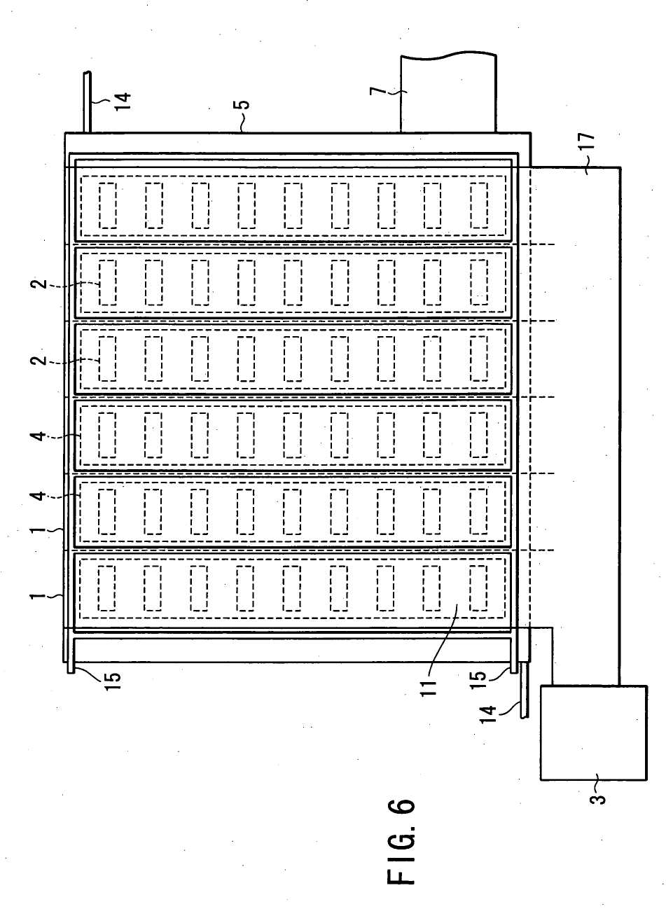

FIG. 4A is a cross sectional view showing the construction of a plasma processing apparatus according to embodiment 3 of the present invention, and FIG. 4B shows in a magnified figure of a portion 4B shown in FIG. 4A. Also, FIG. 5 is an upper view showing the arrangement of a water cooling pipe included in the plasma processing apparatus according to embodiment 3 of the present invention. Further, FIG. 6 is an upper view showing the arrangement of the gas introducing pipe provided with a plurality of gas inlets and included in the plasma processing apparatus according to embodiment 3 of the present invention.

A reference numeral 13 shown in FIG. 4B denotes an O-ring, which is arranged for vacuum sealing the electromagnetic wave radiation window 4 and the beam body 11 of the vacuum chamber 5. A water cooling pipe 14, which serves to allow a cooling water for controlling the temperature to flow therethrough, is arranged within the beam body 11. A plurality of gas introducing pipes 15 for allowing a gas to flow into the vacuum chamber 5 are arranged on the side of the lower portion of the dielectric body member 12. Further, a gas inlet 16 is formed to extend in the longitudinal direction of the gas introducing pipe 15 in a plurality of portions (the forming portion of the gas introducing pipe 15 is omitted in FIG. 5). It is desirable for the gas introducing pipe 15, which can be formed of a metal, to be formed of a dielectric body such as quartz. It is also possible for the dielectric body member 12 and the gas introducing pipe 15 to be formed as an integral body made of a dielectric body. Alternatively, it is possible for a gas introducing pipe to be formed within the dielectric body member 12. In other words, gas can be introduced through the electric body, which is formed to have a pipe shape or a plate shape to distribute the gas to the vacuum chamber like a shower plate of the conventional chemical vapor deposition equipment.

In embodiment 3 of the present invention, the water cooling pipe 14 is formed within the beam body 11 supporting the electromagnetic wave radiation windows 4 in a region positioned between the adjacent electromagnetic wave radiation windows 4. It should be noted that the beam body 11 of the vacuum chamber 5 and the O-ring 13 to keep vacuum at the electromagnetic wave radiation window 4 are heated by the plasma so as to be deformed or damaged. Such being the situation, it is necessary to cool the beam body 11. In embodiment 3 of the present invention, the water cooling pipe 14 is formed within the beam body 11 so as to make it possible to cool efficiently the beam body 11 and the O-ring 13 without obstructing the plasma generation.

Also, a plurality of gas inlets 16 are formed in the gas introducing pipe 15 for supplying a gas for the plasma processing within the vacuum chamber 5 below the beam body 11 for holding the electromagnetic wave radiation windows 4 in a region between the adjacent electromagnetic wave radiation windows 4. The gas inlets 16 make it possible to supply the gas uniformly onto the substrate 8 having a large area without obstructing the plasma generation. It follows that it is possible to carry out a plasma processing with a high uniformity. Incidentally, it is of course possible to arrange any one of the water cooling pipe 14, the gas introducing pipe 15 and the gas inlets 16 of the particular construction.

(Embodiment 4)

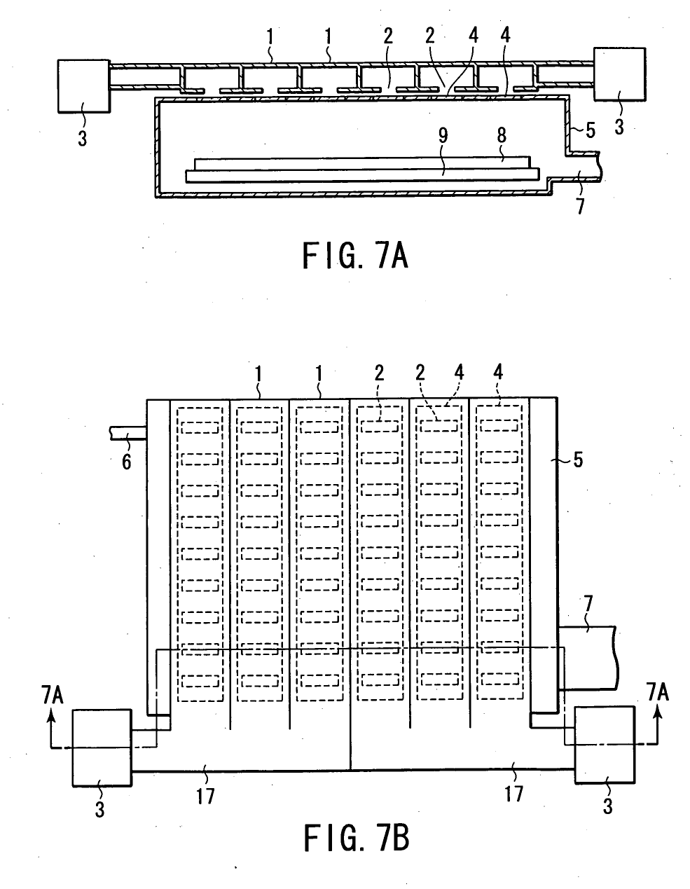

FIG. 7A is a cross sectional view showing the construction of a plasma processing apparatus according to embodiment 4 of the present invention, and FIG. 7B is an upper view of the plasma processing apparatus shown in FIG. 7A. Incidentally, FIG. 7A is a cross sectional view along the line 7A-7A shown in FIG. 7B.

Where the maximum output of the micro wave source 3 is sufficient for achieving a uniform plasma processing, it is possible for a single micro wave source 3 to supply the micro wave as in embodiment 1. However, the area to be processed is limited by the supply power of the micro wave from the single micro wave source 3. Since the maximum output of the micro wave source 3 is limited, a plurality of micro wave sources 3, i.e., two micro wave sources 3 in the drawings, are arranged in embodiment 4 so as to permit a micro wave to be supplied from the plural micro wave sources 3. If a micro wave is supplied from a plurality of micro wave sources 3, a large power can be handled so as to realize a plasma processing apparatus capable of subjecting a large area to the plasma processing.

By arranging two micro wave sources 3 as in embodiment 4, it is possible to process an area two times as large as the area that can be processed by a single micro wave source 3. For example, in the case of a plasma processing apparatus including a single micro wave source of 10 kW, it is possible to process a substrate having a size not larger than 100 cm×120 cm. However, in the case of a plasma processing apparatus including two electromagnetic wave sources of 10 kW, it is possible to subject a substrate having a size not larger than 140 cm×170 cm to a uniform plasma processing. It is also possible to increase the plasma density and to shorten the plasma processing time.

However, in the case of a plasma processing apparatus including a plurality of micro wave sources 3, the micro waves generated from the plural micro wave sources 3 interfere each other so as to change the plasma characteristics and to lower the stability. Such being the situation, it is desirable for the plasma processing apparatus including a plurality of micro wave sources 3 to be designed and adjusted such that the frequencies of the adjacent micro wave sources 3 differ from each other. In this case, it is possible for the plasma processing apparatus to lessen the interference between the adjacent micro wave source 3 so as to prevent the interference of the micro waves and to increase the stability.

Further, the micro wave source 3 having a frequency of 2.45 GHz is manufactured on the basis of the mass production and, thus, is adapted for use in the plasma processing apparatus of the present invention. It follows that the plasma processing apparatus can be manufactured at a low manufacturing cost by using the micro wave source having a frequency of 2.45 GHz. Also, it is possible to change slightly the frequency in the micro wave source 3 of 2.45 GHz so as to make it possible to make the adjacent micro wave sources 3 different from each other in the frequency.

(Embodiment 5)

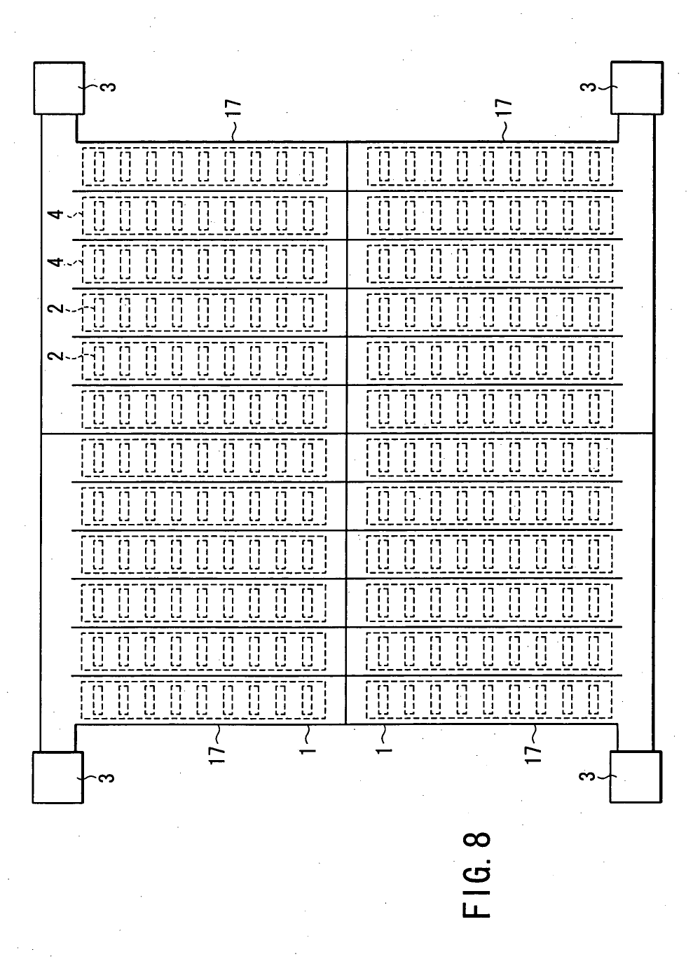

FIG. 8 is an upper view showing the construction of a plasma processing apparatus according to embodiment 5 of the present invention.

In embodiment 5 of the present invention, used are 4 electromagnetic wave sources, e.g., 4 micro wave sources 3, so as to make it possible to process a substrate having an area 4 times as large as the area that can be processed with a single micro wave source 3. For example, in the case of a plasma processing apparatus using 4 electromagnetic wave sources of 10 kW, it is possible to process a substrate having a size of 200 cm×240 cm.

(Embodiment 6)

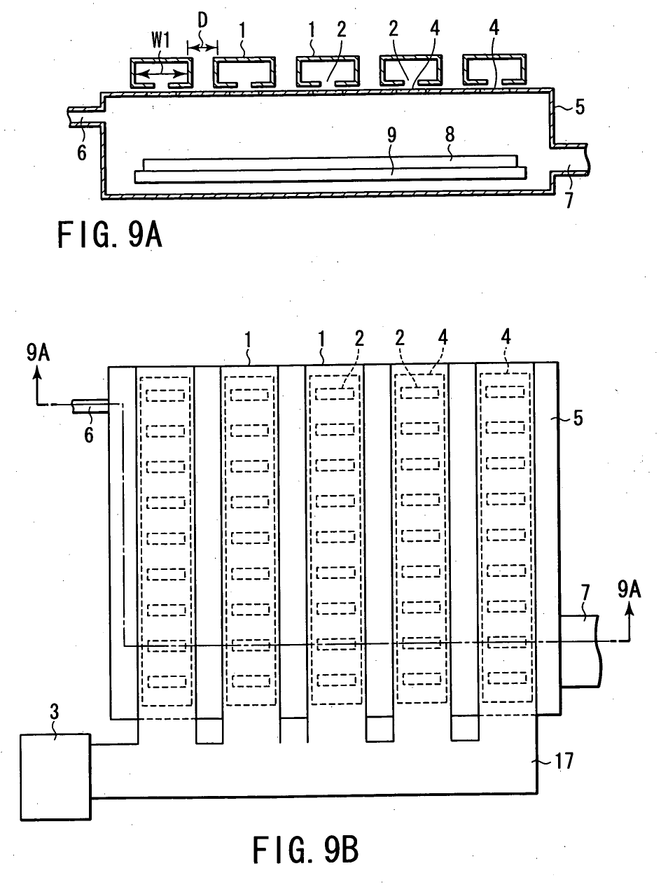

FIG. 9A is a cross sectional view showing the construction of a plasma processing apparatus according to embodiment 6 of the present invention, and FIG. 9B is an upper view showing the plasma processing apparatus shown in FIG. 9A. Incidentally, FIG. 9A is a cross sectional view along the line 9A-9A shown in FIG. 9B.

As described previously, the technical idea of the present invention that a plurality of rectangular waveguides 1 are arranged in contact with each other naturally includes the idea that the distance D between the inner walls of the adjacent rectangular waveguides 1 is not larger than the width W between the inner surfaces of the rectangular waveguide 1. In embodiment 6, the shortest width W₁ between the mutually facing inner surfaces of the rectangular waveguide 1 is set at 9 cm, and the distance D between the inner surfaces of the adjacent rectangular waveguides 1 is set at 3 cm. The distance between the adjacent rectangular waveguides 1 is determined to permit an electromagnetic wave to be radiated uniformly within the vacuum chamber 5 through the electromagnetic wave radiation windows 4.

The emitted light from the plasma generated by the electromagnetic wave from the rectangular waveguides 1 arranged apart from each other was observed by a CCD camera using Charge Coupled Device (CCD) located at the lower wall of vacuum chamber 5. According to this experiment, where a plurality of rectangular waveguides 1 are arranged close to each other such that the distance D between the inner surfaces of the adjacent rectangular waveguides 1 is not larger than the width W₁ between the mutually facing inner surfaces of the rectangular waveguide 1, a plasma was generated uniformly within the vacuum chamber 5. The experimental data support that it is desirable to arrange a plurality of rectangular waveguides 1 close to each other such that the distance D between the inner surfaces of the adjacent rectangular waveguides 1 is not larger than the width W₁ between the mutually facing inner surfaces of the rectangular waveguide 1.

(Embodiment 7)

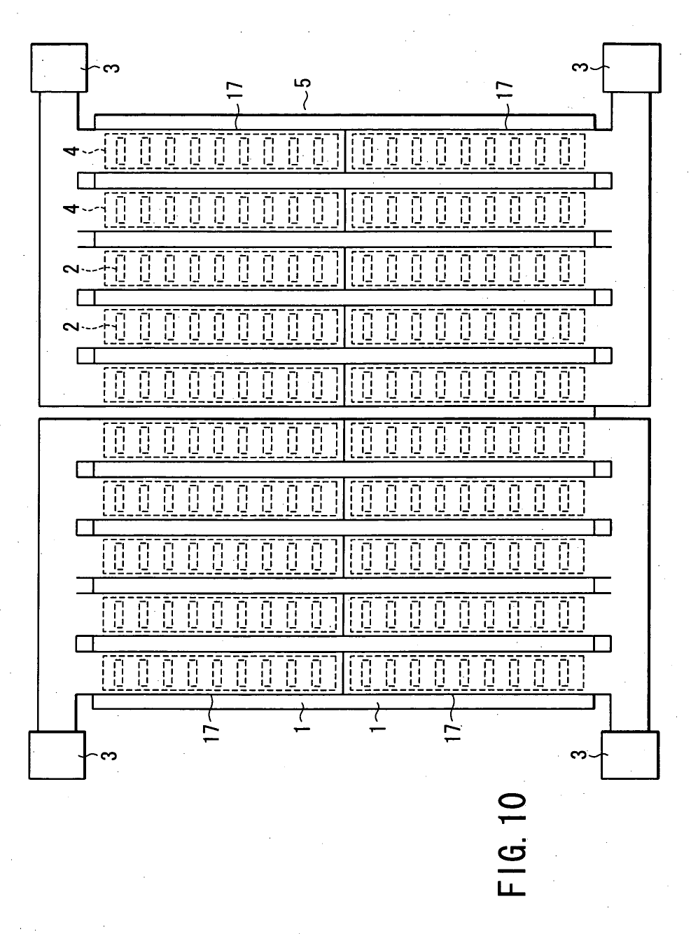

FIG. 10 is an upper view showing the construction of a plasma processing apparatus according to embodiment 7 of the present invention.

Embodiment 7 is substantially based on the embodiment 6, except that, in embodiment 7 of the present invention, used are 4 electromagnetic wave sources, e.g., 4 micro wave sources 3, so as to make it possible to process a substrate having an area 4 times as large as the area that can be processed with a single micro wave source 3. For example, in the case of using 4 electromagnetic wave sources of 10 kW, it is possible to process a substrate having a size not larger than 200 cm×240 cm.

(Embodiment 8)

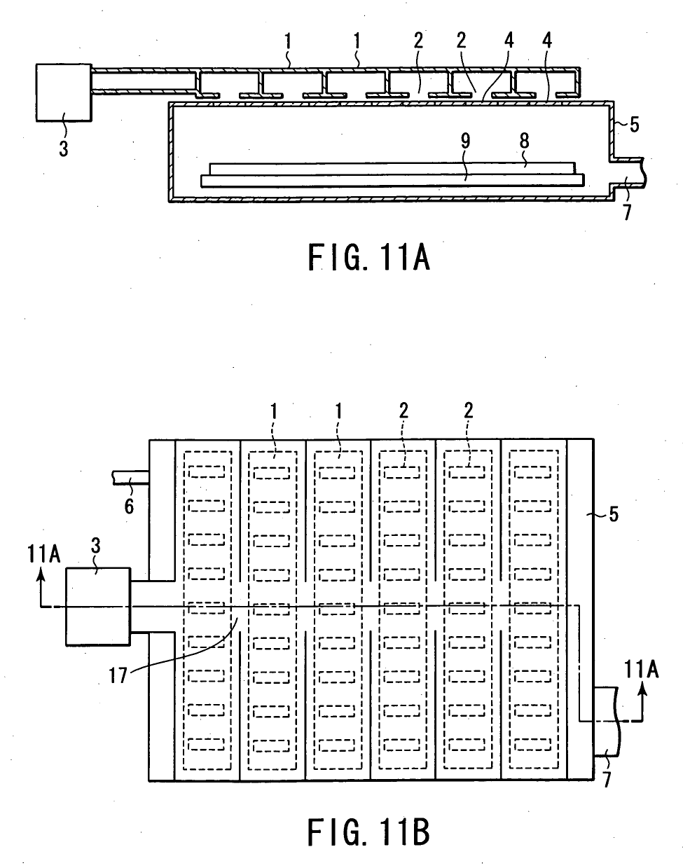

FIG. 11A is a cross sectional view showing the construction of a plasma processing apparatus according to embodiment 8 of the present invention, and FIG. 11B is an upper view showing the plasma processing apparatus shown in FIG. 11A. Incidentally, FIG. 11A is a cross sectional view along the line 11A-11A shown in FIG. 11B.

In embodiment 8 of the present invention, the micro wave generated in the micro wave source 3 is branched at a linear electromagnetic wave distributing waveguide portion 17 having a rectangular cross section so as to be distributed and transmitted into the waveguides 1 extending leftward and rightward so as to be emitted from the slots 2 constituting a waveguide antenna into the vacuum chamber 5 through the electromagnetic wave radiation windows 4. The waveguides 1 and the electromagnetic wave distributing waveguide portion 17 are arranged on the same plane in embodiment 8, too. In embodiment 8, a large number of waveguides 1 are branched leftward and rightward from the electromagnetic wave distributing waveguide portion 17 in substantially the right angles. As shown in FIG. 11B, it is possible to form the slots in the portion of the electromagnetic wave distributing waveguide portion 17. In this case, the plasma is generated uniformly.

Compared with embodiments 1, 2, etc., embodiment 8 of the present invention gives rise to a difficulty. It is difficult to design the electromagnetic wave distributing waveguide portion 17 serving to distribute the electromagnetic wave leftward and rightward. However, it is unnecessary to arrange the electromagnetic wave distributing waveguide portion 17 additionally. It make possible to obtain a compact plasma processing apparatus. Embodiment 8 of the present invention is also featured in that the length of the entire waveguide is short and, thus, the plasma can be made uniform easily in the longitudinal direction of the waveguide.

(Embodiment 9)

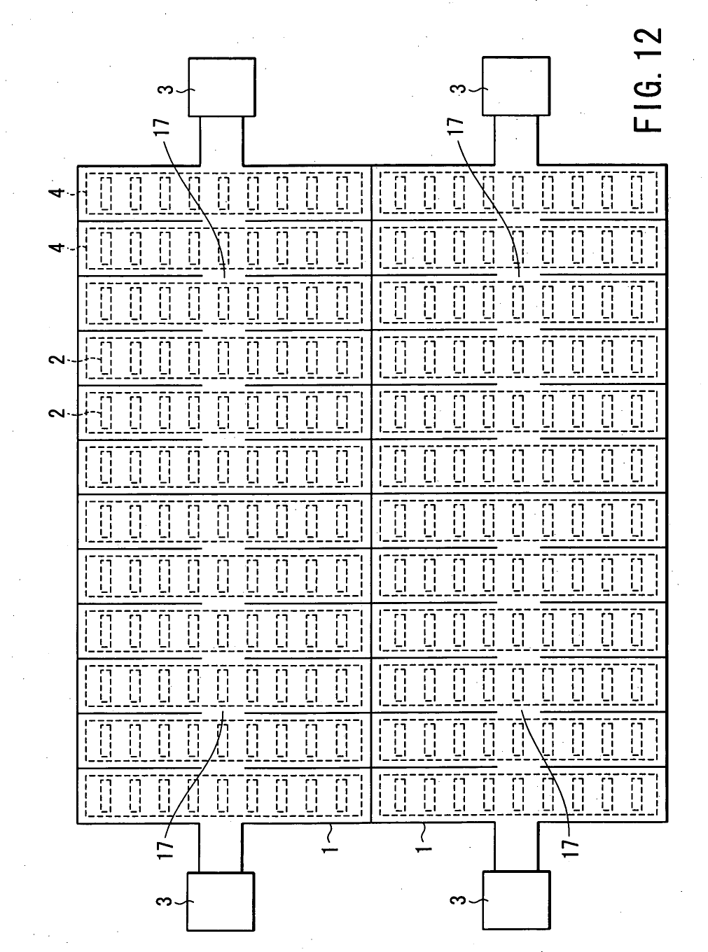

FIG. 12 is an upper view showing the construction of a plasma processing apparatus according to embodiment 9 of the present invention.

Embodiment 9 is substantially based on the embodiment 8, except that, in embodiment 9 of the present invention, used are 4 electromagnetic wave sources, e.g., 4 micro wave sources 3, so as to make it possible to process a substrate having an area 4 times as large as the area that can be processed with a single micro wave source 3. For example, in the case of using 4 electromagnetic wave sources of 10 kW, it is possible to process a substrate having a size not larger than 200 cm×240 cm.

(Embodiment 10)

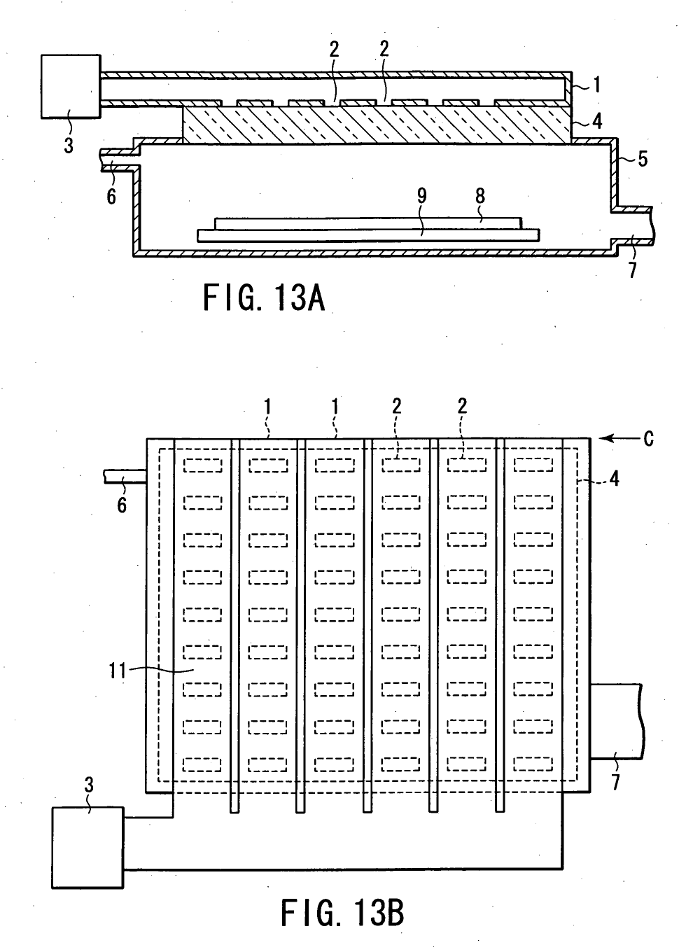

FIG. 13A is a cross sectional view showing the construction of a plasma processing apparatus according to embodiment 10 of the present invention, and FIG. 11B is an upper view showing the plasma processing apparatus shown in FIG. 13A. Incidentally, FIG. 13A is a cross sectional view as viewed in the direction denoted by an arrow C shown in FIG. 13B, unlike the cross sectional view shown in FIG. 1A. FIG. 13A and FIG. 13B do not correspond to each other in the formed sites of the gas inlet 6 and the gas evacuation port 7.

As described previously, if the pressure within the vacuum chamber 5 is reduced, a difference in the gas pressure between the atmospheric pressure and pressure substantially close to vacuum, i.e., about 9.80665×10⁴ Pa (1 kg/cm²), is applied to the electromagnetic wave radiation window 4. It follows that it is necessary to allow the electromagnetic wave radiation window 4 to have a thickness large enough to withstand the pressure difference noted above. For example, when it comes to an electromagnetic wave radiation window 4 made of quartz and sized at 70 cm×60 cm, it is possible for a single electromagnetic wave radiation window 4 to withstand the pressure difference, if the electromagnetic wave radiation window 4 has a thickness of 70 mm. Embodiment 10 of the present invention covers the case of using a single electromagnetic wave radiation window 4. In this case, it is possible to obtain a merit that there is no influence of the electromagnetic wave caused by the beam body 11. It should be noted, however, that, where the plasma processing apparatus includes a single electromagnetic wave radiation window 4 and the substrate is sized at 100 cm square or more, the thickness of the electromagnetic wave radiation window 4 is rendered excessively large so as to make it difficult to obtain a satisfactory plasma processing apparatus.

(Embodiment 11)

Described in the following is the manufacturing process of a polycrystalline silicon thin film transistor (poly-Si TFT) for a liquid crystal display and the other displays formed on a glass substrate by using the plasma processing apparatus according to the embodiment of the present invention described above.

Described first are the positioning of the poly-Si FTF and the specification required for the gate insulating film.

The low temperature polycrystalline silicon thin film transistor (poly-Si TFT) has electrical characteristics higher than those of the conventional amorphous silicon thin film transistor (a-Si TFT). Since it is possible to form various electric circuits on a glass substrate for a liquid crystal display and the other displays, the low temperature poly-Si TFT is highly hopeful. One of the key technologies of the low temperature poly-Si TFT is the formation of a gate insulating film.

The gate insulating films for the low temperature poly-Si TFT and for the integrated circuit are used for the same purpose, but quite differ from each other in the required specification. First of all, the process temperature of the gate insulating film for the integrated circuit is 950° C. or higher. However, it is necessary to set the process temperature for the TFT at 600° C. or lower in the case of using a glass substrate and at 200° C. or lower in the case of using a plastic substrate. Also, when it comes to the substrate area, the single crystal Si wafer for the integrated circuit has a diameter of 30 cm. On the other hand, the glass substrate for the TFT has an area of more than about 70 cm×90 cm, which is about more than 9 times as large as the single crystal Si wafer noted above. It will be necessary for the glass substrate for the TFT to cover a larger area in future.

On the other hand, when it comes to the surface roughness, it is possible to make smooth on the atomic level the surface of the single crystal Si wafer for the integrate circuit. The future target of Si wafer for the surface roughness is 0.1 nm. When it comes to the surface roughness of the low temperature poly-Si, however, the volume is increased when the molten silicon is changed from the liquid phase into the solid phase starting with the nucleus so as to achieve the crystal growth. Finally, the poly-Si surface is upheaved at the grain boundary where the crystal grains collide against each other so as to form a projection of about 50 nm. Also, the island-like step of the poly-Si in the channel portion is 50 nm to 200 nm. It follows that it is necessary to develop a gate insulating film sufficiently capable of covering the projection and the step of the island for in the low temperature poly-Si TFT.

When it comes to the difference in the required specification of the electrical defect density of the gate insulating film, the area of the single element is 900 cm² for the 15 inches liquid crystal display, which is 600 times as large as 1.5 cm² for the PC processor included in the integrated circuit. The channel area constituting the central portion of the transistor is 1.0 μm×1.0 μm for the smallest TFT in contrast to 0.14 μm×0.14 μm for the integrated circuit. The channel area is further increased for the peripheral circuit to reach a level that is about 100 times as large as the channel area for the integrated circuit. The number of TFTs within the liquid crystal screen is: 1600×1200×3=5760,000 for UXGA. The number of transistors included in the peripheral integrated circuit incorporated in the TFT substrate is considered to be on the order of several millions, though the number noted above differs depending on the circuit incorporated in the TFT substrate. It follows that the total number of transistors included in the system panel including the peripheral circuit is several times as large as that for the peripheral integrated circuit. Such being the situation, the sum of the channel areas within a single device in the case of the low temperature poly-Si TFT is estimated to be several hundred times as large as that in the case of the integrated circuit. In other words, in order to make the production yield of the TFT single panels substantially equal to that of the integrated circuit single chip, it is necessary for the electrical defect density of the gate insulating film to be made one over several hundreds.

As described above, it is absolutely necessary to develop the insulating film-forming technology adapted for the low temperature poly-Si TFT and satisfying the required specification given below in the case of the low temperature poly-Si TFT unlike the case of the integrated circuit:

(1) To form the insulating film at low temperatures lower than 600° C.

(2) To cover uniformly a large area and a large irregularity.

(3) To improve the electrical defect density remarkably.

(4) To form a good Si/SiO₂ interface.

Such being the situation, it is desired that a plasma processing apparatus capable of applying oxidation, deposition and etching to a square substrate having a large area by using a plasma of a high density and a low damage.

The formation process will now be described in conjunction with the formation of a polycrystalline silicon thin film transistor (poly-Si TFT) for a liquid crystal on a glass substrate by using the plasma processing apparatus according to the embodiment of the present invention.

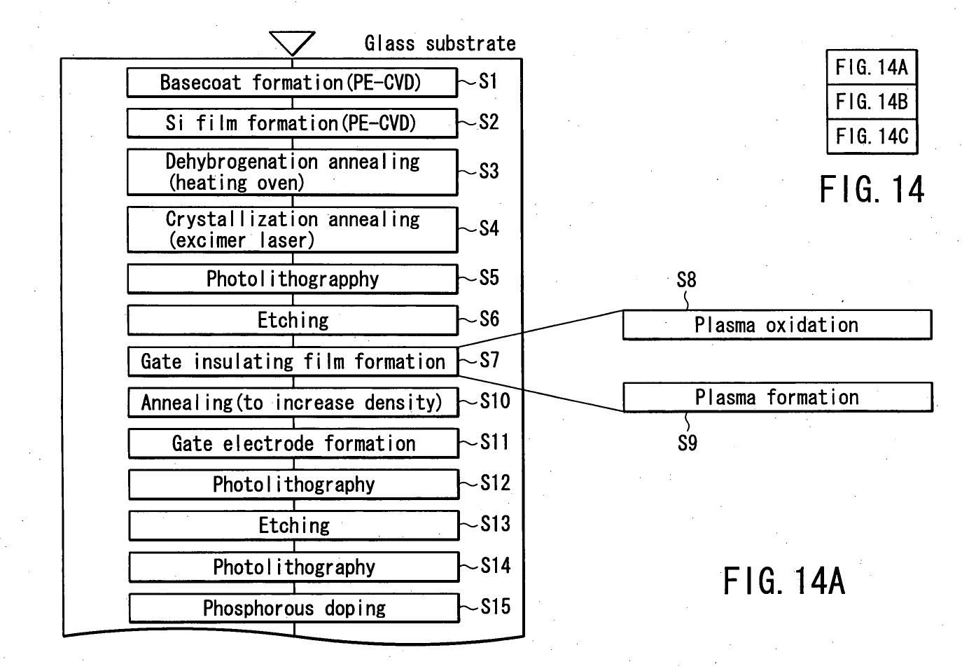

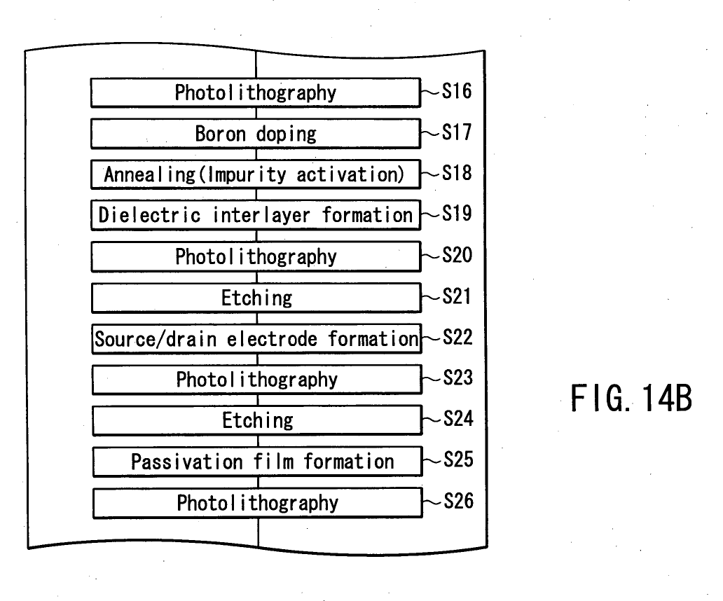

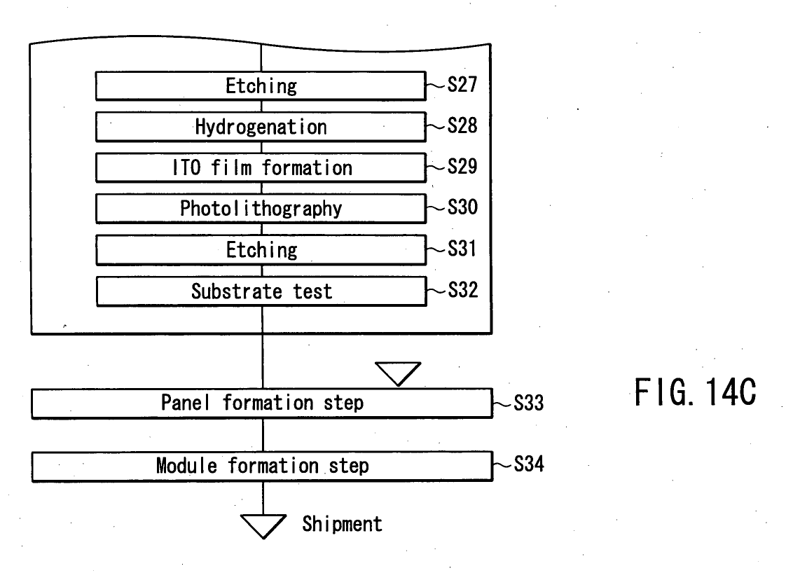

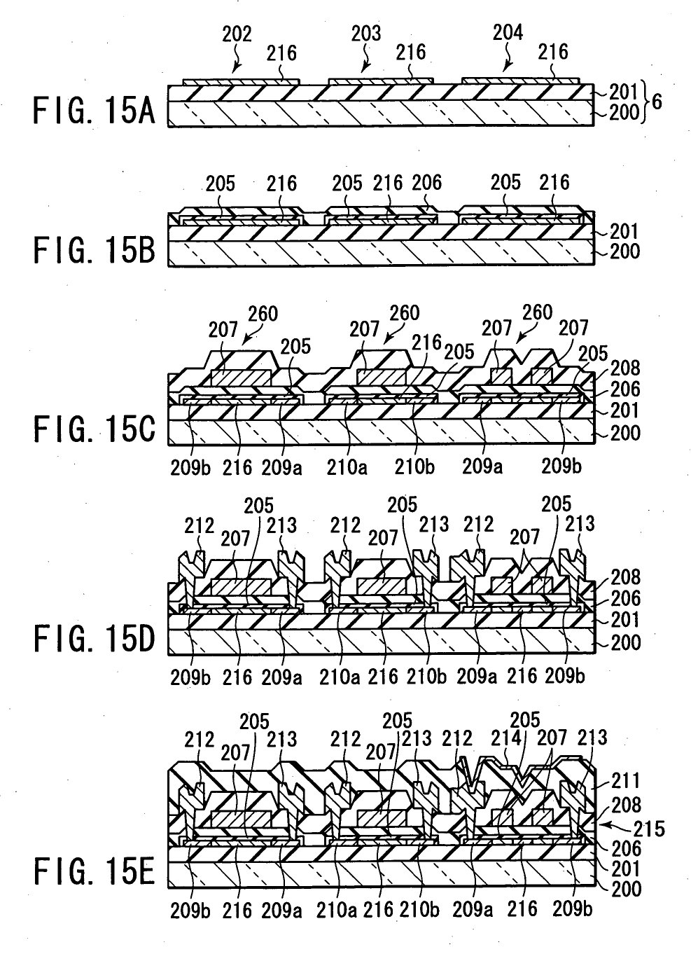

FIG. 14 is a process flow chart of the formation of an n-channel type and p-channel type polycrystalline silicon thin film transistor, using the plasma processing apparatus of the present invention is used for the manufacture of an n-channel type and p-channel type polycrystalline silicon thin film transistor for a liquid crystal display. FIGS. 15A to 15E are cross sectional views each showing the element in the individual process stage.

A glass substrate sized at 700 mm×600 mm×1.1 mm was used as a glass substrate 200 shown in FIG. 15A.

In the first step, a silicon oxide film (SiO₂ film) having a thickness of 200 nm was formed as a base coat film 201 on a cleaned glass substrate 200 by a Plasma Enhanced Chemical Vapor Deposition (PE-CVD) method (PE-CVD method) by using a mixture gas of TEOS gas and O₂ gas (step S1 shown in FIG. 14A). Then, an amorphous silicon film was deposited in a thickness of 50 nm by the PE-CVD method using a SiH₄ gas and a H₂ gas (step S2).

Since the amorphous silicon film contained 5 to 15 atomic percent of hydrogen, the hydrogen is turned gaseous, if the amorphous silicon film is irradiated with a laser beam, with the result that the volume of the hydrogen is rapidly increased so as to cause the film to be blown away. Such being the situation, the glass substrate 200 having the amorphous silicon film was maintained for about one hour at 350° C. or higher at which the hydrogen bond was broken so as to release the hydrogen (step S3).

In the next step, the amorphous silicon film deposited on the glass substrate 200 was irradiated with a pulse laser light (670 mJ/pulse) having a wavelength of 308 nm. The light was emitted from a xenon chloride (XeCl) excimer laser light source and formed to have a cross section of 0.8 mm×130 mm by an optical system, at an intensity of 360 mJ/cm². After the amorphous silicon was melted upon absorption of the laser light so as to form a liquid phase, the temperature was lowered so as to solidify the liquid phase, thereby obtaining a polycrystalline silicon. The laser light is a pulse of 200 Hz, and the melting and the solidification are finished within the time of one pulse. Therefore, the melting and solidification are repeated by the laser light irradiation for every pulse. It is possible to achieve the crystallization over a large area by repeating the movement of the glass substrate 200 and the laser light irradiation. In order to suppress the nonuniformity of the characteristics, the laser light irradiation was performed by overlapping the individual laser light irradiating regions by 95 to 97.5% (step S4).

In the next step, the polycrystalline silicon layer was patterned by the photolithography process (step S5) and the etching process (step S6) so as to form island-shaped polycrystalline silicon layers 216 corresponding to the source, channel and drain regions, respectively, as shown in FIG. 15A. As a result, formed were an n-channel TFT region 202, a p-channel TFT region 203 and a pixel portion TFT region 204, as shown in FIG. 15A.

Then, an insulating film was formed on the most important channel region of the poly-Si TFT (step S7). The apparatus shown in FIG. 1 in conjunction with embodiment 1 of the present invention was used as the plasma processing apparatus.

In the first step, the glass substrate 200 having the island-shaped polycrystalline silicon layers 216 formed on the base coat film 201 as shown in FIG. 15A was set on the support table 10. Then, an argon gas and an oxygen gas mixed at a mixing ratio Ar/(Ar+O₂) of 95% were introduced into the reaction chamber and the pressure within the reaction chamber was maintained at 80 Pa. Under this condition, power of 5 kW was supplied from the micro wave source of 2.45 GHz into the reaction chamber so as to form an oxygen plasma, thereby carrying out a plasma oxidation.

In the oxygen plasma, the oxygen gas is decomposed into an oxygen atom which is active species having a high reactivity. The island-shaped polycrystalline silicon layers 216 are oxidized by the oxygen atom so as to form a plasma oxide film consisting of SiO₂ and forming a gate insulating film 205, i.e., a first insulating film shown in FIG. 15B. The first gate insulating film (first insulating film) 205 having a thickness of about 3 nm was formed in 3 minutes (step S8).

In the next step, the gas for the plasma oxidation was evacuated, followed by introducing a TEOS gas and an oxygen gas into the reaction chamber at a gas flow rate of 30 sccm and 750 sccm, respectively, for forming SiO₂ without breaking the vacuum condition within the film-forming chamber 25 and with the substrate temperature maintained at 350° C., thereby forming a second gate insulating film (second insulating film) 206 consisting of a SiO₂ by a PE-CVD method. For performing the PE-CVD method, the pressure within the film-forming chamber 25 was set at 267 Pa (2 Torr) and the power of the micro wave source was set at 450 W. The second gate insulating film 206 was formed in a thickness of 30 nm in 2 minutes (step S9).

It is possible to carry out the plasma oxidation process (step S8) and the film-forming process (step S9) for forming the second gate insulating film 206 by the PE-CVD method under a high plasma density with a low damage consecutively under the vacuum without lowering the productivity. As a result, it was possible to form a good interface between the semiconductor (island-shaped polycrystalline silicon layer 216) and the first gate insulating film 205 and to form a thick insulating film that have a sufficient breakdown voltage. It is also possible to carry out the film formation by the plasma oxidation and the film formation by the plasma CVD method in separate reaction chambers.

The subsequent process steps were carried out as in the conventional method, thereby manufacturing a poly-Si TFT.

To be more specific, the density of the first gate insulating film 205 consisting of a SiO₂ film was increased by applying an annealing treatment to the glass substrate 200 for 2 hours under a nitrogen gas atmosphere, with the substrate temperature maintained at 350° C. (step S10). By applying the annealing, the density of the SiO₂ is increased so as to reduce to the leak current and increase the breakdown voltage.

Then, after a Ti film was formed by a sputtering method in a thickness of 100 nm as a barrier metal film, an Al film was formed by a sputtering method in a thickness of 400 nm (step S11). The metal film made of Al and Ti was patterned (step S13) by a photolithography method (step S12) so as to form a gate. electrode 207 as shown in FIG. 15C.

In the next step, the p-channel TFT 203 alone was covered with a photoresist in the photolithography process (step S14), followed by doping an n⁺-type source•drain contact portion of an n-channel TFT 202 with phosphorus at a concentration of 6×10¹⁵/cm² by an ion doping method with the gate electrode 207 used as a mask. The ion doping was carried out under an accelerating energy of 80 keV so as to form an n⁺-type source region 209a and an n⁺-type drain region 209b (step S15).

After formation of the n⁺-type source region 209a and the n⁺-type drain region 209b , the n-channel TFT region 202 and the pixel portion TFT region 204 were covered with a photoresist in the photolithography process (step S16), followed by doping a p⁺-source•drain contact portion included in a p-channel TFT 203 (shown in FIG. 15C) with boron by an ion doping method with the gate electrode 207 used as a mask. The ion doping was carried out at a concentration of 1×10¹⁶/cm² under an accelerating energy of 60 keV so as to form a p⁺-type source region 210a and a p⁺-type drain region 210b (step S17).

In the next step, the glass substrate 200 was annealed for 2 hours with the substrate temperature maintained at 350° C. so as to activate phosphorus and boron introduced into the glass substrate 200 by the ion doping method (step S18). Then, an interlayer insulating film 208 consisting of SiO₂ was formed by the PE-CVD method using a TEOS gas and O₂ gas as shown in FIG. 15C (step S19).

In the next step, contact holes leading to the n⁺-type source region 209a , the n⁺-type drain region 209b , the p⁺-type source region 210a and the p⁺-type drain region 210b were formed by the patterning in the interlayer insulating film 208 and second gate insulating film 206 and first gate insulating film 205, by the photolithography process (step S20) and the etching process (step S21). Further, after a Ti film was formed as a barrier metal film in a thickness of 100 nm by a sputtering method, an Al and Ti film was formed on the Ti film in a thickness of 400 nm by a sputtering method, followed by patterning the Al film by a photolithography method (step S23) and an etching method (step S24) so as to form a source electrode 213 and a drain electrode 212, as shown in FIG. 15D.

Still further, a passivation film 211 consisting of a SiO₂ film was formed by a PE-CVD method in a thickness of 300 nm as shown in FIG. 15E (step S25), followed by patterning a contact hole leading a drain region 212 of the n-channel TFT 260 (shown in FIG. 15C) formed in the region of the pixel portion TFT 204 by the photolithography process (step S26) and the etching process (step S27).

After formation of the contact hole noted above, a hydrogen plasma processing was carried out for 3 minutes within a one-by-one type multi-chamber sputtering apparatus, with the substrate temperature set at 350° C., with the H₂ flow rate set at 1000 sccm, with the gas pressure set at 173 Pa (1.3 Torr), and with the RF power source power set at 450 W (step S28). Then, the substrate was moved into another reaction chamber so as to form an ITO film in a thickness of 150 nm (step S29). Formation of the TFT substrate 215 was completed by patterning the ITO film by the photolithography process (step S30) and the etching process (step S31) so as to form a pixel electrode 214 as shown in FIG. 15E, followed by carrying out the substrate inspection (step S32).

The glass substrates each having the TFT substrate 215 and a color filter formed thereon were coated with a polyimide film, followed by rubbing the polyimide film and subsequently bonding these glass substrates to each other. Further, the bonded substrate was cut into each panel.

The panel thus obtained was put in a vacuum vessel, and the injection port of the panel was dipped in a liquid crystal material which put in a dish. Under this condition, an air was introduced into the vacuum vessel so as to cause the liquid crystal to be injected into the gap of the panel by the air pressure. Then, the injection port of the panel was sealed with a resin, thereby completing the formation of a liquid crystal panel (step S33).

Finally, a polarizer film was attached to the liquid crystal panel, followed by mounting a peripheral circuit, a back light, a bezel, etc. to the liquid crystal panel, thereby completing the assemble of a liquid crystal module (step S35).

The liquid crystal module thus prepared by be used in, for example, a personal computer, a monitor, a television receiver set, and a portable terminal.

It should be noted that, in the prior art, a plasma oxide film was not used, and a SiO₂ film was formed by the ordinary PE-CVD method. In this case, the threshold voltage of a TFT was 1.9V±0.8V. In embodiment 11 of the present invention, however, an interface between a silicon oxide and a silicon is formed within a polycrystalline silicon film. As a result, it is possible to obtain good interface characteristics between a silicon oxide and a polycrystalline silicon (island-shaped polycrystalline silicon layer 216). The bulk characteristics of the insulating films can be improved by employing the high-density, low-damage PE-CVD method that utilizes micro waves.

Because of the improvement in the interface characteristics and in the bulk characteristics, the threshold voltage was improved to 1.5V±0.6V. Further, since the uniformity of the threshold voltage has been improved, the production yield has been improved remarkably. It should also be noted that the coverage has been improved by the stacked structure consisting of a plasma oxide film and a plasma CVD film by the high density and the low damage plasma. Further, since the film formed by the PE-CVD method exhibits good characteristics, a leak current was not increased even if the thickness of the gate insulating film was decreased from the conventional level, which was 80 to 100 nm, to 30 nm, which is about ⅓ of the thickness in the conventional level. As a result, it was possible to improve the on-current to a level about 3 times as high as that in the conventional level.

Also, for evaluating the interface characteristics, a silicon single crystal wafer (p-type, 8 to 12 Ω·cm, and a diameter of 150 mm) was set on a glass substrate, and a insulator film was formed by the method equal to that in embodiment 11. Then, an aluminum film was formed by a vacuum vapor deposition utilizing a resistance heating by using a mask provided with a hole having a diameter of 1 mm. Further, the silicon single crystal wafer with the insulator was baked at 400° C. for 30 minutes within a mixed gas consisting of 96% of a nitrogen gas and 4% of a hydrogen gas. The interface trap density, when measured by using the device of the MOS structure, was found to be 3×10¹⁰ cm⁻²eV⁻¹, supporting good interface characteristics equivalent to those of the thermal oxide film.

According to embodiments 1 to 11 of the present invention described above, it is possible to provide a plasma processing apparatus and a plasma processing method, which are highly effective for forming by the plasma oxidation a thin gate insulating film having good interface characteristics with a silicon layer for forming a channel of a low temperature poly-Si TFT for a liquid crystal display panel using the glass described above as a substrate.

(Embodiment 12)

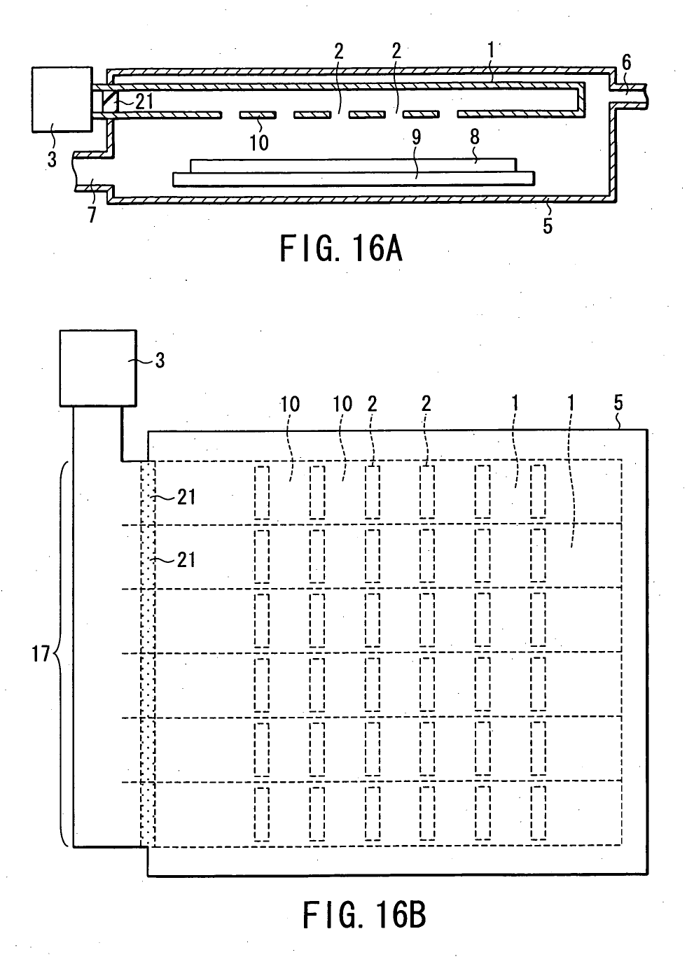

FIG. 16A is a cross sectional view showing the construction of a plasma processing apparatus according to embodiment 12 of the present invention, and FIG. 16B is an upper view showing the plasma processing apparatus shown in FIG. 16A.

In embodiment 12 of the present invention, a waveguide, e.g., a rectangular waveguide 1, is located within the vacuum chamber 5. A dielectric body member 21 made of quartz, glass or a ceramic material is arranged in the inlet port portion of the rectangular waveguide 1. Also, a reference numeral 22 shown in the drawing denotes beam portion in contact with the rectangular waveguide 1. Incidentally, a gas inlet 6 and a gas evacuation port 7 are omitted in FIG. 16B.

The micro wave generated by the micro wave source 3 is transmitted to the electromagnetic wave distributing waveguide portion 17 and distributed into the rectangular waveguide 1, and is then radiated from the slots 2 constituting a waveguide antenna into the vacuum chamber 5 through the dielectric body member 21.

The plasma processing apparatus according to embodiment 12 of the present invention comprises the micro wave source 3, a waveguide, e.g., the rectangular waveguide 1, a plurality of slots 2 formed on the rectangular waveguide 1 and constituting an waveguide antenna, and the vacuum chamber 5. The plasma is formed by the electromagnetic wave radiated from the slots 2 into the vacuum chamber 5 so as to carry out a plasma processing. It should be noted that the rectangular waveguide 1 is arranged within the vacuum chamber 5, and the vacuum condition is maintained by the dielectric body member 21 formed within the rectangular waveguide 1. Also, the electromagnetic wave is introduced through the dielectric body member 21 into the vacuum chamber 5.

Where the plasma processing apparatus is constructed such that the rectangular waveguide 1 is arranged within the vacuum chamber 5, that the vacuum condition is maintained by the dielectric body member 21 formed within the rectangular waveguide 1, and that the electromagnetic wave is introduced through the dielectric body member 21 into the vacuum chamber 5, it is possible to diminish the dielectric body member 21 and to decrease the thickness of the dielectric body member 21. It follows that it is possible to process a substrate having a large area with a uniform plasma density.

What should also be noted is that a plurality of rectangular waveguides 1 (six rectangular waveguides 1 being shown in the drawing) are arranged in contact with each other. The relationship between the shortest distance between the inner wall surfaces of the adjacent rectangular waveguides 1 and the width between the mutually facing inner surfaces of the rectangular waveguide 1 is equal to that described previously in conjunction with embodiment 1. Since the plural rectangular waveguides 1 are arranged in contact with each other, it is possible to permit easily the slots 2 to be distributed uniformly over the entire area that is to be subjected to the plasma processing. It follows that it is possible to process a substrate having a large area with a uniform plasma density. Incidentally, the slots 2 are distributed uniformly over the entire area that is to be subjected to the plasma processing as already described in conjunction with embodiment 1 of the present invention.

Also, the slots 2 are distributed substantially uniformly over the entire area of the substrate 8 that is to be subjected to the plasma processing. Further, a plurality of dielectric body members 21, i.e., six dielectric body members 21 in this case, are arranged to correspond commonly to the plural slots 2, i.e., 6 slots in this case.

In embodiment 12, a micro wave is distributed onto a region of a large angular area by using a plurality of rectangular waveguides 1 arranged in contact with other so as to permit the micro wave to be emitted with a uniform energy density from the slots 2 onto the large area through the dielectric body member 21 so as to generate a plasma having a uniform plasma density.

(Embodiment 13)

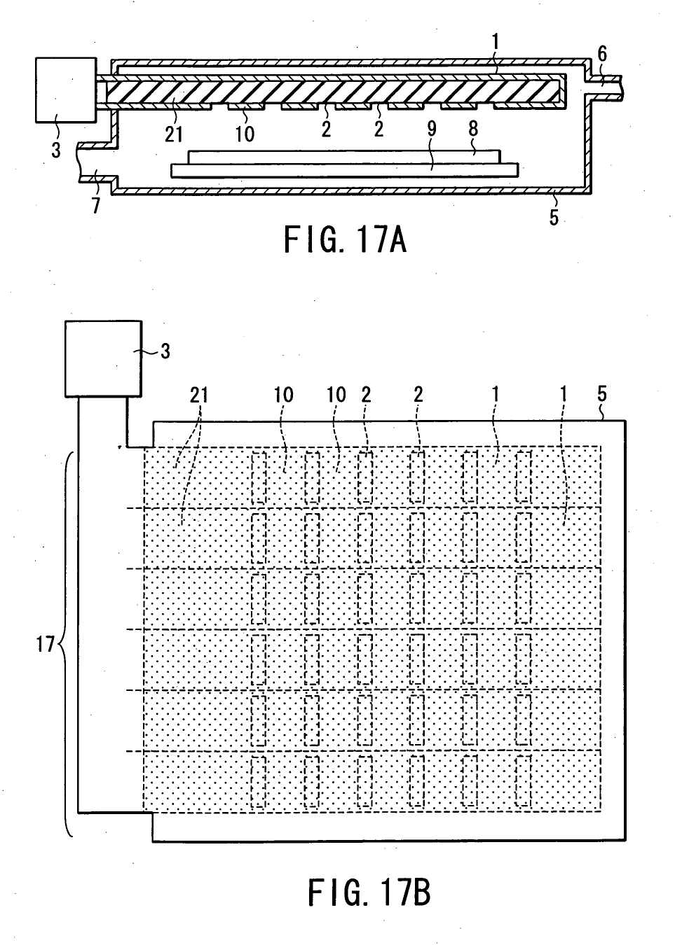

FIG. 17A is a cross sectional view showing the construction of a plasma processing apparatus according to embodiment 13 of the present invention, and FIG. 17B is an upper view showing the plasma processing apparatus shown in FIG. 17A. Incidentally, the gas inlet 6 and the gas evacuation port 7 are omitted in FIG. 17B.

In embodiment 13 of the present invention, the rectangular waveguide 1 positioned within at least the vacuum chamber 1 is filled with the dielectric body member 21. As a result, it is possible to prevent the plasma from entering the rectangular waveguide 1 positioned within the vacuum chamber 5. It follows that it is possible to prevent the inner region of the rectangular waveguide 1 from being damaged by the plasma.

(Embodiment 14)

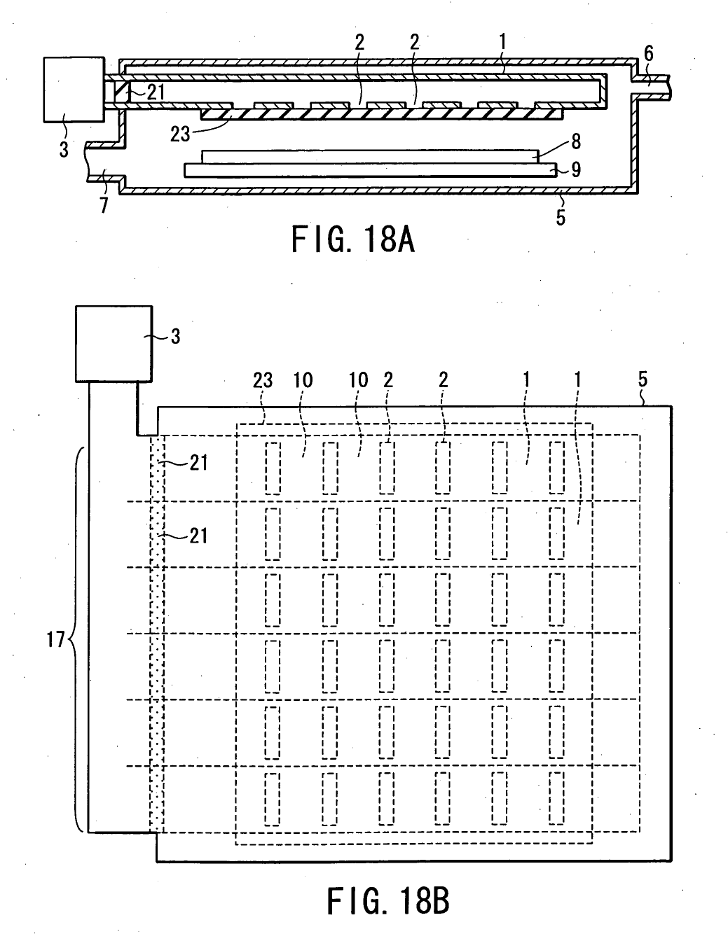

FIG. 18A is a cross sectional view showing the construction of a plasma processing apparatus according to embodiment 14 of the present invention, and FIG. 18B is an upper view showing the plasma processing apparatus shown in FIG. 18A. Incidentally, the gas inlet 6 and the gas evacuation port 7 are omitted in FIG. 18B.

A reference numeral 23 shown in the drawing denotes a rectangular second dielectric body member. In embodiment 14, the second dielectric body member 23 is arranged within the vacuum chamber 5 in a manner to correspond commonly to 36 slots 2, which are arrange to form, for example, 6 columns each consisting of 6 slots 2.

In embodiment 14 of the present invention, the electromagnetic wave tends to be expanded within the second dielectric body member 23 formed in a lower portion of the entire waveguide antenna formed of a plurality of slots 2 formed in the rectangular waveguide 1 made of a metal. Also, the slot 2 is not exposed to the plasma. It follows that it is possible to form a plasma of a higher uniformity, compared with the case where the second dielectric body member 23 is not included in the plasma processing apparatus.

Also, in embodiment 14 of the present invention, the second dielectric body member 23 serves to prevent the plasma from entering the rectangular waveguide 1 arranged within the vacuum chamber 5, with the result that the inner region of the rectangular waveguide 1 is prevented from the damaged of the plasma.

Incidentally, a single second dielectric body member 23 is included in the plasma processing apparatus according to embodiment 14 of the present invention. However, it is possible to divide the second dielectric body 12 into a plurality of sections. Incidentally, it is possible to arrange the second dielectric body member 23 in the plasma processing apparatus according to embodiment 13 of the present invention shown in FIGS. 17A and 17B so as to obtain the similar effects.

(Embodiment 15)

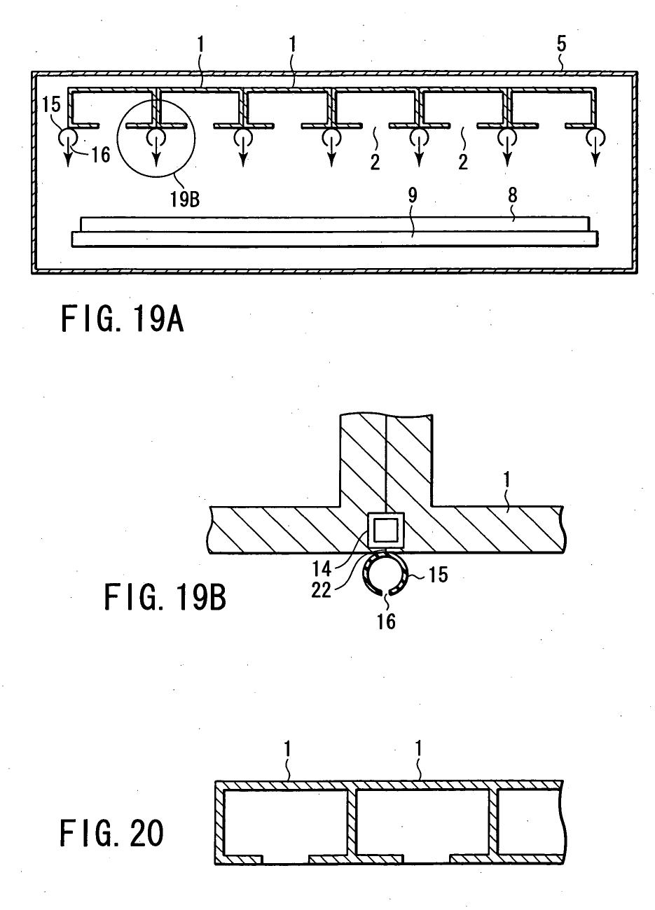

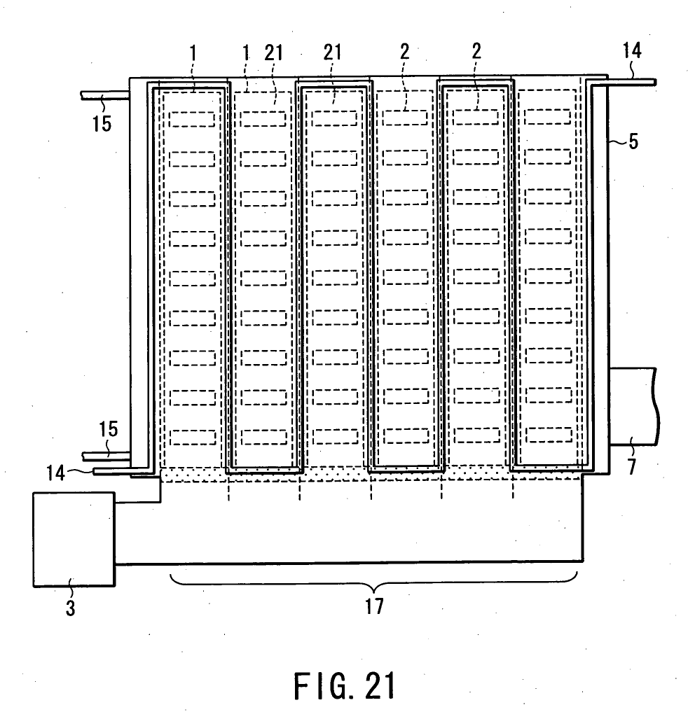

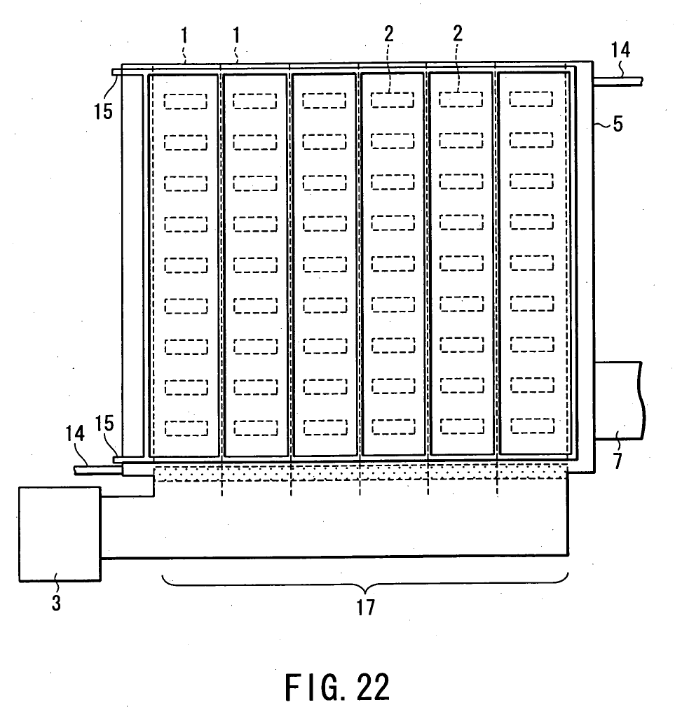

FIG. 19A is a cross sectional view showing the construction of a plasma processing apparatus according to embodiment 15 of the present invention. The cross sectional view shown in FIG. 19A is perpendicular to the cross sectional view shown in each of FIGS. 16A, 17A and 18A. On the other hand, FIG. 19B shows in an magnified fashion portion A (beam portion 22) shown in FIG. 19A. Further, FIG. 21 is an upper view showing the arrangement of a water cooling pipe included in the plasma processing apparatus according to embodiment 15. Still further, FIG. 22 is an upper view showing the arrangement of the gas introducing pipe provided with a plurality of gas inlets and included in the plasma processing apparatus according to embodiment 15 of the present invention.

A water cooling pipe 14 through which flows a cooling water is formed within the beam portion 22 in contact with the rectangular waveguide 1. The gas introducing pipe 15 for allowing a gas to flow into the vacuum chamber 5 is also arranged below the portion in contact with the rectangular waveguide. Also, the gas inlets 16 formed in a plurality of points of the gas introducing pipe 15 are equal to those described previously in conjunction with embodiment 1. The portion in which the gas introducing pipe 15 is formed is not shown in FIG. 6. It is desirable for the gas introducing pipe 15, which can be formed of a metal, to be formed of a dielectric body.

In embodiment 15, the water cooling pipe 14 is formed within the beam portion 22 of the rectangular waveguide 1, the beam portion 22 being positioned between two adjacent slots 2. Cooling is required to prevent deformation and damage to the slot 2 etc. heated by plasma. In embodiment 15 of the present invention, the cooling can be achieved efficiently without obstructing the plasma generation.

Also, a plurality of gas inlets 16 are formed within the vacuum chamber 5 so as to be positioned below the beam portion 22 between the adjacent slots 2. Since these gas inlets 16 make it possible to supply a gas uniformly onto the substrate 8 having a large area without obstructing the plasma generation, it is possible to carry out the plasma processing with a high uniformity.

In embodiment 15, the water cooling pipe 14 and the gas introducing pipe 15 having the gas inlets 16 formed therein are arranged in the plasma processing apparatus according to embodiment 12 of the present invention shown in FIGS. 16A and 16B. However, it is also possible to form the water cooling pipe 14 and the gas introducing pipe 15 in the plasma processing apparatus according to embodiment 13 of the present invention shown in FIGS. 17A and 17B. Of course, it is possible to use any of the water cooling pipe 14 of the particular construction and the gas introducing pipe 15 having the gas inlets 16 formed therein.

In embodiment 15, it is possible to prepare a plurality of rectangular waveguides 1 and to assemble these plural rectangular waveguides 1 such that these waveguides 1 are in contact with each other so as to form a waveguide planar antenna, as shown in FIG. 19A. In this case, it is possible to obtain the effect produced by embodiment 12 even if these rectangular waveguides 1 are arranged several centimeters apart from each other.

FIG. 20 is a cross sectional view exemplifying another construction of the rectangular waveguide that can be used in embodiment 15. Specifically, embodiment 15 of the present invention will now be described, covering the case where, for example, the effective processing area is 70 cm×60 cm. To be more specific, concerning the specific manufacturing method of the rectangular waveguide 1, six rectangular waveguides 1 each having a width within the rectangular waveguide 1 of 9 cm and a height of 3 cm were prepared by shaving an aluminum block sized at 70 cm×60 cm×4 cm. In this case, the wall of the adjacent rectangular waveguides 1 was formed integral, as shown in FIG. 20.

(Embodiment 16)

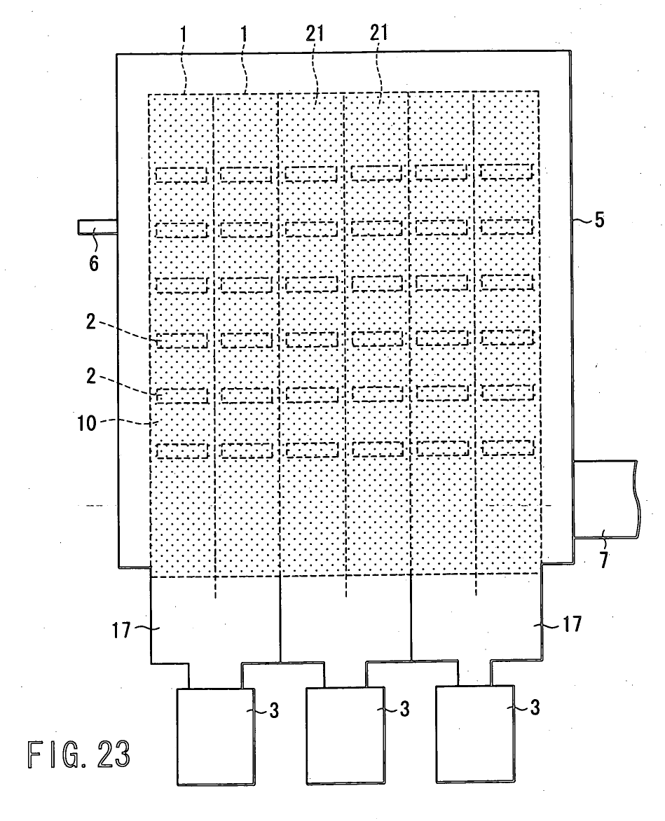

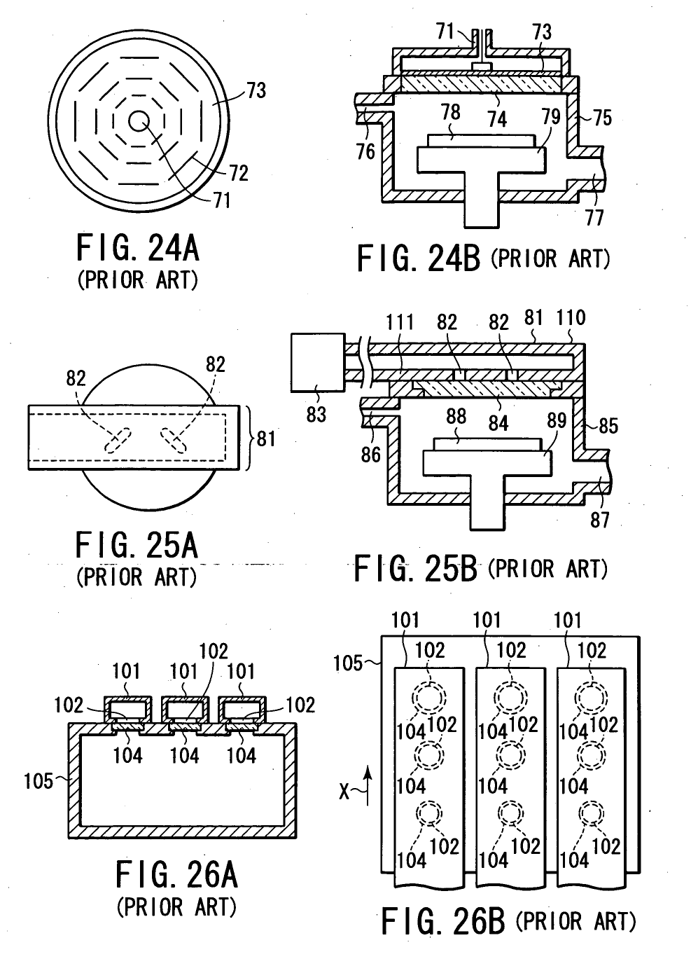

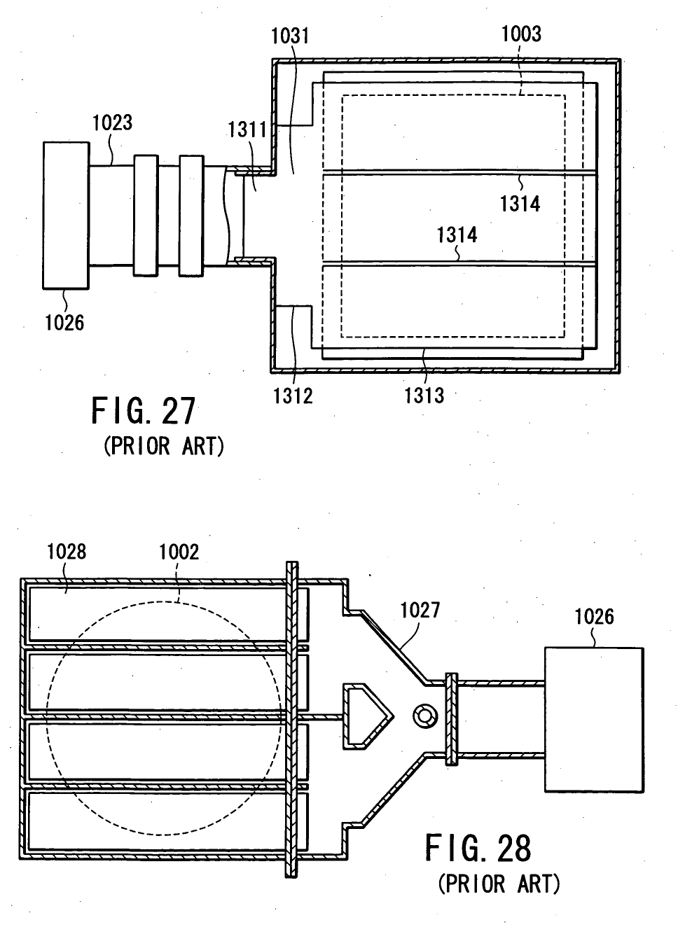

FIG. 23 is an upper view showing the construction of a plasma processing apparatus according to embodiment 16 of the present invention. In the plasma processing apparatus according to embodiment 16 of the present invention, used are a plurality of micro wave sources 3 for supplying an electromagnetic wave into the rectangular waveguide 1 arranged within the vacuum chamber 5.

Where the micro wave source 3 has a sufficiently large maximum output, it is possible to use a single micro wave source 3 for supplying the micro wave as in embodiment 12. However, the processing area is limited by the output of the micro wave source 3. Since the maximum output of the micro wave source 3 is limited, it is desirable to arrange a plurality of micro wave sources 3 as in embodiment 16 so as to supply a micro wave from the plural micro wave sources 3. In this case, a large power can be handled so as to make it possible to provide a plasma processing apparatus capable of processing a large area. It is also possible to increase the plasma density and to shorten the plasma processing time.

However, in the case of using a plurality of micro wave sources 3, some issues are produced by the micro waves generated from the plural micro wave sources 3 so as to change the plasma characteristics and to lower the stability. Such being the situation, it is possible to use a plurality of micro wave sources 3 and to allow the adjacent micro wave sources 3 to differ from each other in the frequency so as to decrease the influences given by the plural micro wave sources 3, to prevent the interference and to increase the stability.

As described previously, the micro wave source 3 having a frequency of 2.45 GHz is manufactured on the mass production basis. Therefore, the plasma processing apparatus can be manufactured with a low manufacturing cost by using the micro wave source 3 manufactured on the mass production basis. What should also be noted is that it is possible to change slightly the frequency of the micro wave source 3 having a frequency of 2.45 GHz so as to make it possible to arrange the micro wave sources 3 such that the adjacent micro wave sources 3 are allowed to differ from each other in the frequency.

In embodiment 16, a plurality of micro wave sources 3 are arranged in the plasma processing apparatus according to embodiment 13 of the present invention shown in FIGS. 17A and 17B. Of course, it is also possible to arrange a plurality of micro wave sources 3 in the plasma processing apparatus according to embodiment 12 of the present invention shown in FIGS. 16A and 16B.

Incidentally, each of embodiments 1 to 16 of the present invention described above is intended to facilitate the understanding of the present invention, and is not intended to limit the technical scope of the present invention. For example, a micro wave source is used mainly as the electromagnetic wave source in each of the embodiments of the present invention. However, the electromagnetic wave source used in the present invention is not limited to the micro wave source. Also, the electromagnetic wave distributing waveguide portion included in the plasma processing apparatus of the present invention is shaped linear in each of embodiments described above. However, the electromagnetic wave distributing waveguide portion is not limited to a linear electromagnetic wave distributing waveguide portion. It is possible for the electromagnetic wave distributing waveguide portion used in the present invention to be curved or folded. Also, the cross sectional shape of the waveguide, which is rectangular in each of the embodiments described above, is not particularly limited. It follows that each of the factors disclosed in embodiments 1 to 16 described above should be construed to include all the design modifications and equivalents thereto belonging to the technical scope of the present invention.

What is claimed is:

1. A plasma processing apparatus for performing a plasma processing, comprising an electromagnetic wave source for generating an electromagnetic wave, a waveguide, a plurality of slots formed on the waveguide and constituting a waveguide antenna, an electromagnetic wave radiation window consisting of a dielectric body, and a vacuum chamber, wherein a plasma is generated by an electromagnetic wave radiated from the slots into the vacuum chamber through the electromagnetic wave radiation window, the plasma processing apparatus being constructed such that:
the plasma processing apparatus includes a plurality of the waveguides, which are arranged in contact with each other;
the plasma processing apparatus includes an electromagnetic wave distributing waveguide portion for distributing the electromagnetic wave from the electromagnetic wave source into the plural waveguides; and
the electromagnetic wave radiation window constitutes a part of the wall of the vacuum chamber, and the vacuum condition is retained between the electromagnetic wave radiation window and the other wall of the vacuum chamber.

2. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
each of the plural waveguides is branched from the electric field plane or the plane perpendicular to the magnetic field plane of the electromagnetic wave distributing waveguide portion.

3. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber arranged to include the electromagnetic wave radiation window as an incident plane of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
the transmission direction of the electromagnetic wave is bent at substantially right angles in the electromagnetic wave distributing waveguide portion so as to permit the electromagnetic wave to be distributed into the plural waveguides.

4. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of an dielectric body and arranged to face the plural slots, and a vacuum chamber arranged to include the electromagnetic wave radiation window as an incident surface of the electromagnetic wave, wherein the plasma processing apparatus is constructed such that:
a plasma is generated by the electromagnetic wave radiated from the slots into the vacuum chamber through the electromagnetic wave radiation window;
the plasma processing apparatus includes a plurality of the waveguides;
the electromagnetic wave distributing waveguide portion serves to distribute the electromagnetic wave generated from the electromagnetic wave source into each of the plural waveguides;
each of the plural waveguides is branched from the electric field plane of the electromagnetic wave distributing waveguide portion; and
the electromagnetic wave distributing waveguide portion and the plural waveguides are arranged on substantially the same plane.

5. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber arranged to include the electromagnetic wave radiation window as an incident surface of the electromagnetic wave, wherein the plasma processing apparatus is constructed such that:
a plasma is generated by the electromagnetic wave radiated from the slots into the vacuum chamber through the electromagnetic wave radiation window so as to carry out the plasma processing;
the plasma processing apparatus includes a plurality of the waveguides;
the electromagnetic wave distributing waveguide portion serves to distribute the electromagnetic wave generated from the electromagnetic wave source into each of the waveguides; and
the shortest distance between the inner surfaces of the adjacent waveguides is not larger than the width between the inner surfaces of the one waveguide.

6. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber arranged to include the electromagnetic wave radiation window as an incident surface of the electromagnetic wave, wherein the plasma processing apparatus is constructed such that:
a plasma is generated by the electromagnetic wave radiated from the slots into the vacuum chamber through the electromagnetic wave radiation window;
the plasma processing apparatus includes a plurality of the waveguides;
the electromagnetic wave distributing waveguide portion serves to distribute the electromagnetic wave generated from the electromagnetic wave source into each of the plural waveguides; and
the plural waveguides are branched from the electromagnetic wave distributing waveguide portion toward both side.

7. The plasma processing apparatus according to claim 6, wherein the plural waveguides are branched at substantially right angles from the electromagnetic wave distributing waveguide portion toward both sides.

8. The plasma processing apparatus according to claim 6, wherein the electromagnetic wave distributing waveguide portion and the plural waveguides are arranged on substantially the same plane.

9. The plasma processing apparatus according to claim 2, wherein a plurality of electromagnetic wave radiation windows are arranged such that the vacuum condition is maintained between the plural electromagnetic wave radiation windows and the vacuum chamber.

10. The plasma processing apparatus according to claim 3, wherein a plurality of electromagnetic wave radiation windows are arranged such that the vacuum condition is maintained between the plural electromagnetic wave radiation windows and the vacuum chamber.

11. The plasma processing apparatus according to claim 4, wherein a plurality of electromagnetic wave radiation windows are arranged such that the vacuum condition is maintained between the plural electromagnetic wave radiation windows and the vacuum chamber.

12. A plasma processing apparatus, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed in the waveguide and constituting a waveguide antenna, and a vacuum chamber maintaining the vacuum condition, wherein the plasma processing apparatus is constructed such that:
a plasma is generated by the electromagnetic wave radiated from the slots into the vacuum chamber;
at least one waveguide is arranged in the vacuum chamber; and
a dielectric body member constituting a part of the wall surface of the vacuum chamber is formed in the said waveguide, the vacuum condition is maintained by a part of the wall of the waveguide, the dielectric body member, and another part of the vacuum chamber, and the electromagnetic wave is introduced into the vacuum chamber through the dielectric body member.

13. The plasma processing apparatus according to claim 12, wherein the dielectric body member fills substantially the entire volume within the waveguide.

14. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
wherein the slots are distributed substantially uniformly over the entire area that is to be subjected to the plasma processing.

15. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
wherein a plurality of the electromagnetic wave radiation windows are hermetically arranged in a manner to correspond commonly to the plural slots, and the vacuum condition is maintained between the plural electromagnetic wave radiation windows and the vacuum chamber.

16. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
the electromagnetic wave radiation window substantially equal in width to the waveguide is arranged in a manner to correspond to each of the waveguides;
the major axis direction of the waveguide substantially coincides with that of the electromagnetic wave radiation window;
the length in the major axis direction of the waveguide substantially coincides with that of the electromagnetic wave radiation window; and
the period of the major axis of the waveguide substantially coincides with the that of the electromagnetic wave radiation window.

17. The plasma processing apparatus according to claim 16, wherein the length in the major axis direction of the electromagnetic wave radiation window is shorter than that of the waveguide.

18. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
wherein the dielectric body member commonly in contact with at least one electromagnetic wave radiation window is arranged within the vacuum chamber.

19. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
wherein the beam body supporting each of the electromagnetic wave radiation windows on the side of the vacuum chamber is covered with the dielectric body member at least.

20. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
wherein a water cooling pipe for controlling the temperature is arranged within the beam body positioned between the adjacent electromagnetic wave radiation windows for supporting the electromagnetic wave radiation windows or in that portion of the beam body which is in contact with the waveguide.

21. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
wherein a gas introducing pipe is formed within the vacuum chamber below the beam body positioned between the adjacent electromagnetic wave radiation windows for supporting the electromagnetic wave radiation windows or below that portion of the vacuum chamber which is in contact with the waveguide.

22. A plasma processing apparatus for performing a plasma processing, comprising an electromagnetic wave source for generating an electromagnetic wave, an electromagnetic wave distributing waveguide portion for transmitting the electromagnetic wave generated from the electromagnetic wave source, a waveguide connected to the electromagnetic wave distributing waveguide portion, a plurality of slots formed on the waveguide and constituting a waveguide antenna, an electromagnetic wave radiation window consisting of a dielectric body and arranged to face the plural slots, and a vacuum chamber including the electromagnetic wave radiation window as an incident surface of the electromagnetic wave, wherein a plasma is generated by the electromagnetic wave radiated from the slots into the vacuum chamber through the electromagnetic wave radiation window, the plasma processing apparatus being constructed such that:
the plasma processing apparatus includes a plurality of the waveguides;
the electromagnetic wave distributing waveguide portion serves to distribute the electromagnetic wave generated from the electromagnetic wave source into each of the plural waveguides; and
wherein a gas introducing pipe is formed of a dielectric body within the vacuum chamber under the electromagnetic wave radiation windows or integrated the electromagnetic wave radiation windows.

23. The plasma processing apparatus according to claim 6, wherein the slot is formed in the electromagnetic wave distributing waveguide portion, too.
